(19) United States
(12) Patent Application Publication
(10) Pub. No.: US 2004/0202031 A1
(43) Pub. Date: Oct. 14, 2004

(54) Magnetic memory device, data copying apparatus, data copying system, recording medium and data copying method

(76) Inventors: Takeshi Kajiyama, Yokohama-shi (JP); Yoshiaki Fukuzumi, Yokohama-shi (JP); Hiroaki Yoda, Kawasaki-shi (JP); Junichi Miyamoto, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/678,254

(22) Filed: Oct. 6, 2003

(30) Foreign Application Priority Data
Apr. 11, 2003 (JP) 2003-107994
Jun. 16, 2003 (JP) 2003-171217

(51) Int. Cl. G11C 29/00

(52) U.S. Cl. 365/200

(57) ABSTRACT

A data copying method includes connecting a data copying device to a server via a network, selecting first data from a database of the server, downloading the first data into the data copying device, writing the downloaded first data into a first magnetic memory, setting a second magnetic memory in the data copying device, and writing second data into the second magnetic memory by setting the first and second magnetic memories close to each other to magnetically transfer the first data to the second magnetic memory.

### CROSS-REFERENCE TO RELATED APPLICATIONS

This application is based upon and claims the benefit of priority from the prior Japanese Patent Applications No. 2003-107994, filed Apr. 11, 2003; and No. 2003-171217, filed Jun. 16, 2003, the entire contents of both of which are incorporated herein by reference.

### BACKGROUND OF THE INVENTION

1. Field of the Invention

This invention relates to a magnetic memory device, data copying device, data copying system, recording medium and data copying method which copy data by magnetic transferring data.

2. Description of the Related Art

Conventionally, various types of storage media such as an FeRAM are proposed and a data transferring operation is performed by use of the storage media.

FIG. 44 is a comparison table showing times required for downloading data items of storage media which are now considered. As shown in FIG. 44, when considering a case wherein a user downloads data from a content provider, it is understood that the time required for downloading and writing data of 1 GB into a memory medium will become as long as 400 seconds in the normal writing operation even if an FeRAM or MRAM (Magnetic Random Access Memory) which is considered to be the fastest memory is used.

Therefore, for example, when it is considered to download image data of a large capacity into a mobile memory by use of the waiting time for a train in a kiosk or the like in a station, no memory medium among the present storage media can be used if it is assumed that the waiting time for downloading is approximately 30 seconds.

As described above, with the conventional storage media, it takes an extremely long time to download and write data of a large capacity, particularly, large-capacity data such as an image. Therefore, it is considered to be extremely difficult to realize easy data transfer.

### BRIEF SUMMARY OF THE INVENTION

A magnetic memory device according to a first aspect of the present invention comprises a first write wiring formed to extend in a first direction, a first magneto-resistance element arranged above the first write wiring, and a passivation film formed thinner than the first write wiring and disposed on the first magneto-resistance element.

A data copying method according to a second aspect of the present invention comprises connecting a data copying device to a server via a network, selecting first data from a database of the server, downloading the first data into the data copying device, writing the downloaded first data into a first magnetic memory, setting a second magnetic memory in the data copying device, and setting the first and second magnetic memories close to each other to magnetically transfer the first data to the second magnetic memory and write second data into the second magnetic memory.

### BRIEF DESCRIPTION OF THE SEVERAL VIEWS OF THE DRAWING

FIG. 1 is a view showing the principle of a magnetic transferring operation using magnets according to one embodiment of this invention;

FIG. 2 is a view showing the principle of a magnetic transferring operation using magnetic memories (MRAMs) according to another embodiment of this invention;

FIG. 3 is a schematic diagram showing a data copying system according to still another embodiment of this invention;

FIG. 4 is a diagram showing the configuration of a first data copying system according to one embodiment of this invention;

FIG. 5 is a diagram showing the function of the first data copying system according to the above embodiment of this invention;

FIG. 6 is a flow chart showing a first data copying method according to one embodiment of this invention;

FIG. 7 is a diagram showing another configuration of the first data copying system according to the above embodiment of this invention;

FIG. 8 is a diagram showing the configuration of a second data copying system according to one embodiment of this invention;

FIG. 9 is a diagram showing the function of the second data copying system according to the above embodiment of this invention;

FIG. 10 is a flow chart showing a second data copying method according to one embodiment of this invention;

FIG. 11 is a diagram showing a recording medium in which a program used to realize the first data copying method according to the above embodiment of this invention is stored;

FIG. 12 is a diagram showing a recording medium in which a program used to realize the second data copying method according to the above embodiment of this invention is stored;

FIG. 13 is a view showing the basic structure of a packaged magnetic memory according to one embodiment of this invention;

FIG. 14 is a top plan view showing the packaged magnetic memory according to the above embodiment of this invention;

FIG. 15 is a view showing a magnetic memory having a door-type cover portion according to one embodiment of this invention;

FIG. 16 is a view showing a packaged magnetic memory of a card type according to one embodiment of this invention;

FIGS. 17A and 17B are views showing a packaged magnetic memory according to a modification 1 of the above embodiment of this invention;

FIG. 18 is a view showing the state of the magnetic memory of the modification 1 of FIGS. 17A and 17B at the magnetic transferring time;

FIGS. 19A and 19B are views showing a packaged magnetic memory according to a modification 2 of the above embodiment of this invention;

FIG. 20 is a view showing the state of the magnetic memory of the modification 2 of FIGS. 19A and 19B at the magnetic transferring time;

FIG. 21 is a view showing another packaged magnetic memory according to the modification 2 of the above embodiment of this invention;

FIG. 22 is a cross-sectional view showing the first structure of a master magnetic memory according to one embodiment of this invention;

FIG. 23 is a perspective view showing the second structure of the master magnetic memory according to the above embodiment of this invention;

FIG. 24 is a cross-sectional view showing the second structure of the master magnetic memory according to the above embodiment of this invention;

FIG. 25 is a cross-sectional view showing the third structure of a master magnetic memory according to one embodiment of this invention;

FIG. 26 is a cross-sectional view showing the fourth structure of a master magnetic memory according to one embodiment of this invention;

FIG. 27 is a cross-sectional view showing the structure of a customer magnetic memory according to one embodiment of this invention;

FIGS. 28A and 28B are cross-sectional views showing an MTJ element of a single tunnel junction structure according to one embodiment of this invention;

FIGS. 29A and 29B are cross-sectional views showing an MTJ element of a double tunnel junction structure according to one embodiment of this invention;

FIG. 30 is a view showing the positional relation between MTJ elements of the customer magnetic memory and the master magnetic memory according to one embodiment of this invention;

FIG. 31 is a view showing an example of a first aligning mark according to one embodiment of this invention;

FIG. 32 is a view showing the aligning operation by use of an example of the first aligning mark according to the above embodiment of this invention;

FIG. 33 is a view showing an example of a second aligning mark according to one embodiment of this invention;

FIG. 34 is a view showing an example of a third aligning mark according to one embodiment of this invention;

FIGS. 35A and 35B are views showing the relation between the cover portion and aligning mark according to one embodiment of this invention;

FIG. 36 is a plan view showing an inserting type magnetic transfer device according to one embodiment of this invention;

FIG. 37 is a cross-sectional view showing the inserting type magnetic transfer device according to the above embodiment of this invention;

FIG. 38 is a cross-sectional view showing a fitting type magnetic transfer device according to one embodiment of this invention;

FIG. 39 is a cross-sectional view showing a slide inserting type magnetic transfer device according to one embodiment of this invention;

FIG. 40 is a view showing a magnetic memory card cartridge according to one embodiment of this invention;

FIG. 41 is a view showing a driving device according to one embodiment of this invention;

FIG. 42 is a view showing a state before a shutter of the magnetic memory card cartridge is set into an open state by use of the driving device according to the above embodiment of this invention;

FIG. 43 is a view showing a state after the shutter of the magnetic memory card cartridge was set into the open state by use of the driving device according to the above embodiment of this invention;

FIG. 44 is a diagram showing a comparison table showing times required for downloading data items of storage media by use of the conventional technique; and

FIG. 45 is a cross-sectional view showing the MRAM structure of a one-transistor/one-MTJ element in the conventional technique.

### DETAILED DESCRIPTION OF THE INVENTION

In one embodiment of this invention, an attempt is made to reduce data transfer time by magnetic transferring data by use of a magnetic random access memory (MRAM).

There will now be described embodiments of this invention with reference to the accompanying drawings. When explaining this invention, the same reference symbols are attached to like portions throughout the drawings.

1. Principle of Magnetic Transfer:

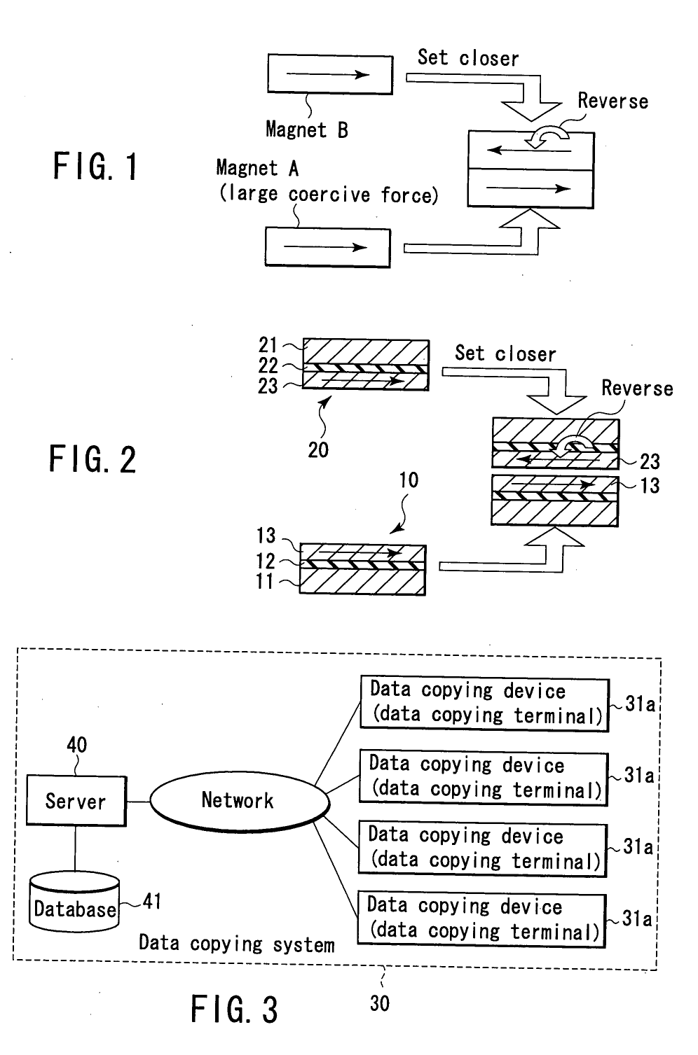

The principle of a magnetic transferring operation is explained with reference to FIGS. 1 and 2.

FIG. 1 shows the principle of the magnetic transferring operation when magnets are used and FIG. 2 shows the principle of the magnetic transferring operation when MRAMs having MTJ (Magnetic Tunnel Junction) elements are used.

As shown in FIG. 1, when two magnets A and B whose magnetism directions are set in the same direction are set closer to each other, the direction of the magnetism of one of the magnets is reversed and the magnetisms tend to be set in opposite directions. At this time, for example, if the coercive force of the magnetism of the magnet A is larger than the coercive force of the magnetism of the magnet B, the direction of the magnetism of the magnet B is reversed.

Likewise, as shown in FIG. 2, it is assumed that an MTJ element 10 of a master magnetic memory (master MRAM) 50 and an MTJ element 20 of a customer magnetic memory (customer MRAM) 60 in which the magnetisms of free layers (recording layers) 13, 23 are set in the same direction are set closer to each other with the free layers 13, 23 facing each other. In this case, for example, if the coercive force of the MTJ element 20 of the customer magnetic memory 60 is smaller than the coercive force of the MTJ element 10 of the master magnetic memory 50, the direction of the magnetism of the free layer 23 of the MTJ element 20 of the customer magnetic memory 60 having the smaller coercive force is reversed or set in a direction opposite to the direction of the magnetism of the free layer 13 of the MTJ element 10 of the master magnetic memory 50 having the larger coercive force.

If the MTJ element 10 of the master magnetic memory 50 and the MTJ element 20 of the customer magnetic memory 60 with the directions of the magnetisms of the free layers 13, 23 thereof set in opposite directions are set closer to each other with the free layers 13, 23 facing each other, the directions of the magnetisms are kept unchanged.

By use of the above principle, this invention is made so as to permit data transfer to be instantly performed.

2. Data Copying Method, Data Copying Device and Data Copying System:

Next, a first data copying method using a first data copying device and data copying system is explained with reference to FIGS. 3 to 8 and a second data copying method using a second data copying device and data copying system is explained with reference to FIGS. 9 to 11.

(1) First Data Copying Method, First Data Copying Device and Data Copying System:

The first data copying method includes a step of downloading data written into the master magnetic memory from the server.

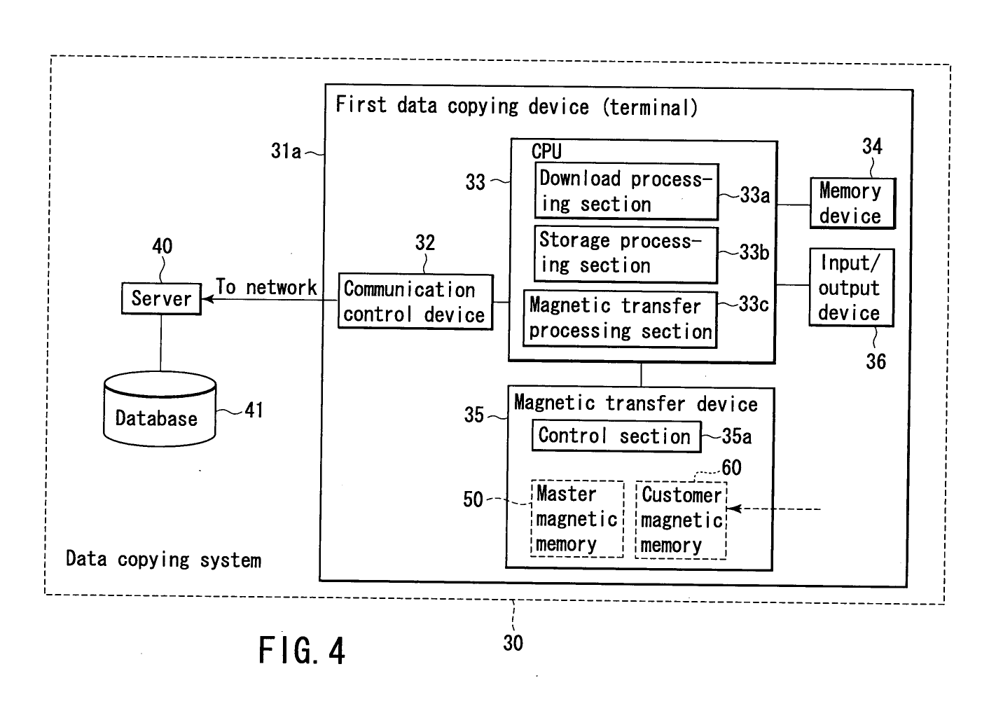

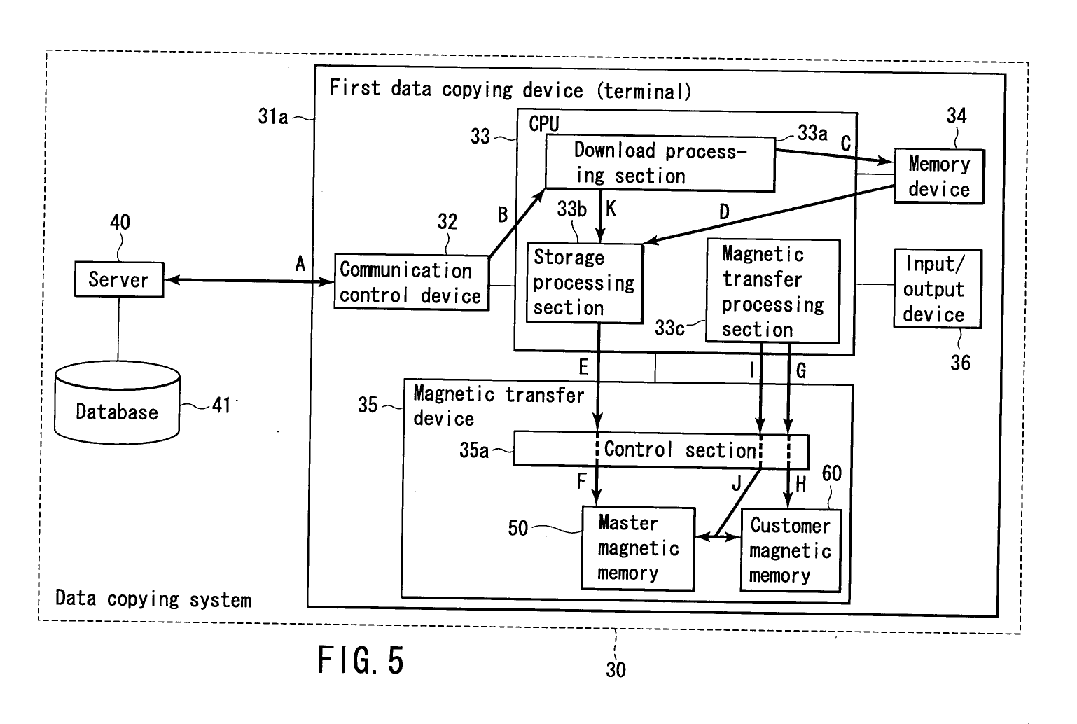

FIG. 3 is a schematic diagram showing the data copying system based on the first data copying method. FIGS. 4 and 5 are a configuration diagram and operation diagram showing the first data copying device in the data copying system. Next, the configurations of the data copying system and first data copying device are explained.

As shown in FIG. 3, a data copying system 30 includes first data copying devices (data copying terminals) 31a, and a server 40 of a content warehouse connected to the first data copying devices via a network such as the Internet. A database 41 configured by various content data items is stored in the server 40.

As shown in FIG. 4, the first data copying device 31a includes a communication control device 32, CPU 33, memory device 34, magnetic transfer device 35 and input/output device 36.

The CPU 33 includes a download processing section 33a, storage processing section 33b and magnetic transfer processing section 33c. The magnetic transfer device 35 includes a control section 35a. The master magnetic memory 50 and customer magnetic memory 60 are inserted into the magnetic transfer device 35.

The constituents of the first data copying device 31a have the following functions.

The communication control device 32 has a function of connecting the first data copying device 31a to the server 40 (instruction A of FIG. 5). For example, the communication control device 32 includes a modem, router, network switch and the like.

The download processing section 33a has a function of receiving an order from a manager of the first data copying device 31a, selecting data corresponding to the order from the database of the server 40, and downloading the selected data into the download processing section 33a (instruction B of FIG. 5). It further has a function of writing the downloaded data into the memory device 34 (instruction C of FIG. 5).

The storage processing section 33b has a function of reading out data written into the memory device 34 (instruction D of FIG. 5) and further has a function of supplying an instruction used to write the readout data into the master magnetic memory 50 to the control section 35a (instruction E of FIG. 5).

The magnetic transfer processing section 33c has a function of receiving an order from a customer and supplying an instruction used to move the customer magnetic memory 60 to a preset copying position to the control section 35a according to the order (instruction G of FIG. 5). It further has a function of supplying an instruction used to copy data of the master magnetic memory 50 into the customer magnetic memory 60 to the control section 35a (instruction I of FIG. 5).

The control section 35a has a function of writing data which has been written into the memory device 34 into the master magnetic memory 50 according to the instruction E (instruction F of FIG. 5) and a function of moving the customer magnetic memory 60 to a copying position according to the instruction G (instruction H of FIG. 5). It further has a function of copying data of the master magnetic memory 50 into the customer magnetic memory 60 according to the instruction I (instruction J of FIG. 5). In this case, the control section 35a can be omitted.

The memory device 34 includes a hard disk, for example, and has a function of temporarily storing data downloaded according to the instruction C.

The input/output device 36 includes a touch panel, for example, and has a function of permitting the user to touch his finger on a button or mark displayed on the display screen so as to input data and output the result of inputting. In this case, the input/output device 36 may be divided into an input device such as a display and an output device such as a keyboard, for example.

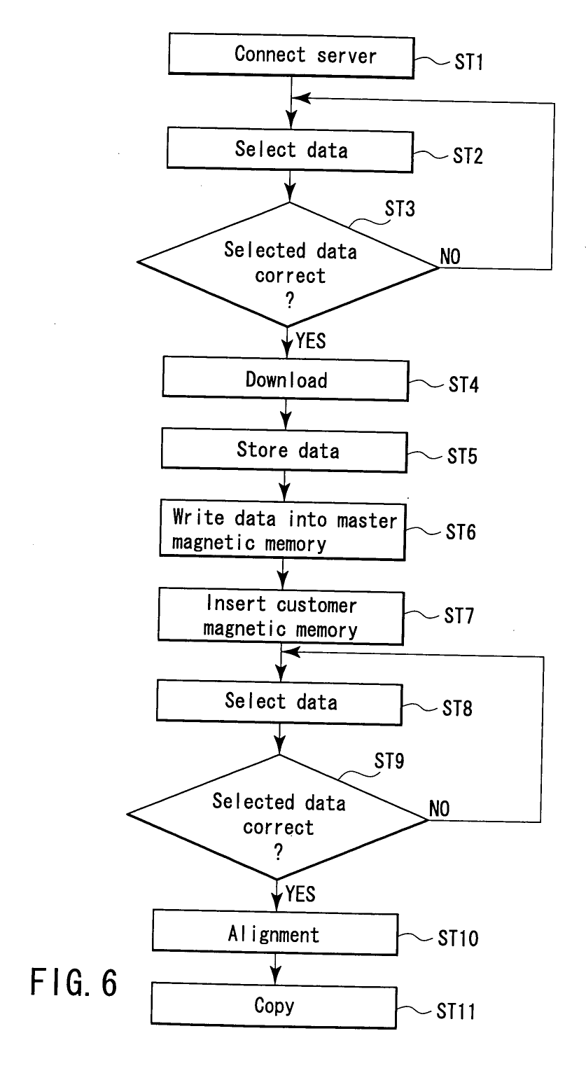

FIG. 6 is a flow chart showing the first data copying method. Next, the first data copying method is explained.

First, the manager of the first data copying device 31a accesses the server 40 of the content warehouse from the first data copying device 31a via a network such as the Internet and connects the first data copying device 31a to the server 40 (ST1).

At this time, the manager inputs a password and ID and attempts to connect the data copying device 31a to the server 40. That is, by previously registering the IDs and passwords, only specified users who are under the contract are permitted to connect their own devices to the server 40.

Next, the manager selects a plurality of necessary content data items from various content data items in the database 41 stored in the server 40 (ST2).

Then, the selected content data items are displayed on the input/output device 36 in a list form and whether the selected content data items are correct or not is checked (ST3). As a result, if the list of the selected content data items is correct, a screen button “OK” is selected and if it is not correct, a screen button “Correction” is selected.

If the screen button “OK” is selected, the manager selects a screen button “Start of Downloading” to download the selected content data from the server 40 to the data copying device 31a (ST4). On the other hand, if the screen button “Correction” is selected, the manager selects necessary data from the various content data again (ST2).

Then, after the downloading operation is completed, a screen of “Completion of Downloading” is displayed. At this time, the downloaded content data is temporarily stored in the memory device 34 of the data copying device 31a (ST5).

Next, the downloaded content data is written into the master magnetic memory 50 (ST6). Then, after the write operation is completed, a screen of “Completion of Writing” is displayed.

By performing the steps ST1 to ST6, preparation is completed so as to permit the customer to utilize the data copying device 31a.

Next, the customer inserts the customer magnetic memory 60 into the magnetic transfer device 35 of the first data copying device 31a in order to copy data (ST7).

Then, the customer selects data to be copied from various content data items (ST8). At this time, since the various content data items are already downloaded, access to the server 40 is not necessary.

The selected content data items are displayed on the input/output device 36 in a list form and whether the selected content data items are correct or not is checked (ST9). As a result, if the list of the selected content data items is correct, a screen button “OK” is selected and if it is not correct, a screen button “Correction” is selected.

If the screen button “OK” is selected, the customer magnetic memory 60 is set closer to the master magnetic memory 50 in which the selected data is stored and the master magnetic memory 50 and customer magnetic memory 60 are aligned with each other (ST10). At this time, the master magnetic memory 50 and customer magnetic memory 60 are set closer with the free layer of the MTJ element of the master magnetic memory 50 and the free layer of the MTJ element of the customer magnetic memory 60 facing each other. For alignment, an optical method, magnetic method or the like may be used. After completion of the alignment, a screen of “Completion of Alignment” is displayed.

On the other hand, if the screen button “Correction” is selected, the customer selects data to be copied from the various content data again (ST8).

Then, after the alignment process is completed, the customer selects a screen of “Start of Copying”. As a result, data of the master magnetic memory 50 is magnetically transferred as one block to the customer magnetic memory 60 (ST11). When the magnetic transferring operation is completed, a screen of “Completion of Copying” is displayed.

At this time, it is desirable to take an ESD (Electro Static Destruction) measure before the magnetic transferring operation. Further, it is preferable to perform the magnetic transferring operation with the master magnetic memory 50 and customer magnetic memory 60 pressed against each other.

The step ST5 (instructions C, D of FIG. 5) can be omitted. That is, the downloaded content data may be directly written into the master magnetic memory 50 without temporarily storing the same into the memory section 34 of the data copying device 31a. In this case, after data is downloaded from the server 40, the download processing section 33a supplies an instruction used to write the data into the master magnetic memory 50 to the storage processing section 33b (instruction K of FIG. 5).

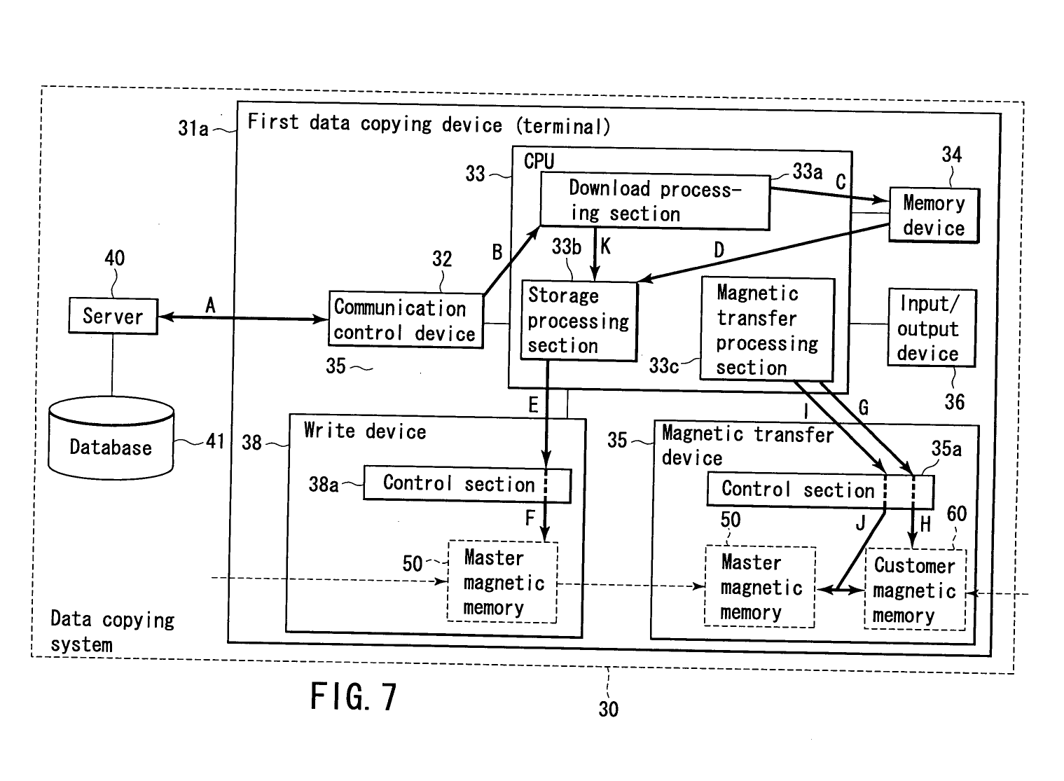

Further, a device which writes data into the master magnetic memory 50 in the step ST6 (instructions E, F of FIG. 5) is not limited to the magnetic transfer device 35. For example, as shown in FIG. 7, a write device 38 for data writing may be newly provided. In this case, the master magnetic memory 50 is first carried into the write device 38. Then, after the data writing operation in the write device 38 is completed, it is carried into the magnetic transfer device 35. In this case, the instruction E is supplied to the control section 38a of the write device 38.

If data is copied from the master magnetic memory 50 to the customer magnetic memory 60 in the step ST11, data is inverted because of the property of the magnetic transferring operation. Therefore, if data to be copied into the customer magnetic memory 60 is used as “reference data”, it is necessary to write “inverted data (negative data)” which is inverted with respect to the reference data into the master magnetic memory 50. To serve the above purpose, inverted data may be previously stored in the database 41 of the server 40. Alternatively, the reference data may be stored in the database 41 of the server 40 and inverted by use of the constituent (for example, storage processing section 33b) of the data copying device 31a and inverted data may be written into the master magnetic memory 50.

Further, when data is copied from the master magnetic memory 50 to the customer magnetic memory 60 in the step ST11, it is necessary to set the coercive force of the master magnetic memory 50 larger than the coercive force of the customer magnetic memory 60 so as to prevent data of the master magnetic memory 50 from being rewritten.

As described above, if the magnetic transferring operation is performed according to the first data copying method by use of the first data copying device, the magnetic transferring operation is performed by setting the master magnetic memory and the customer magnetic memory close to each other, Thus, data of the master magnetic memory can be written into the customer magnetic memory. By thus copying storage information, copy forming time can be markedly reduced. Therefore, since data of a large capacity such as an image can simply be distributed, information distribution of a short period of time in an MRAM which is expected as a large-capacity storage memory and an apparatus used for information distribution can be attained.

(2) Second Data Copying Method and Second Data Copying Device:

The second data copying method is different from the first data copying method in that the step of downloading data into the master magnetic memory via the network is omitted. Therefore, in the second data copying device, the communication control device, download processing section and storage processing section are not provided. As the master magnetic memory used in the second data copying method, a memory which is formed in a ROM form can be used.

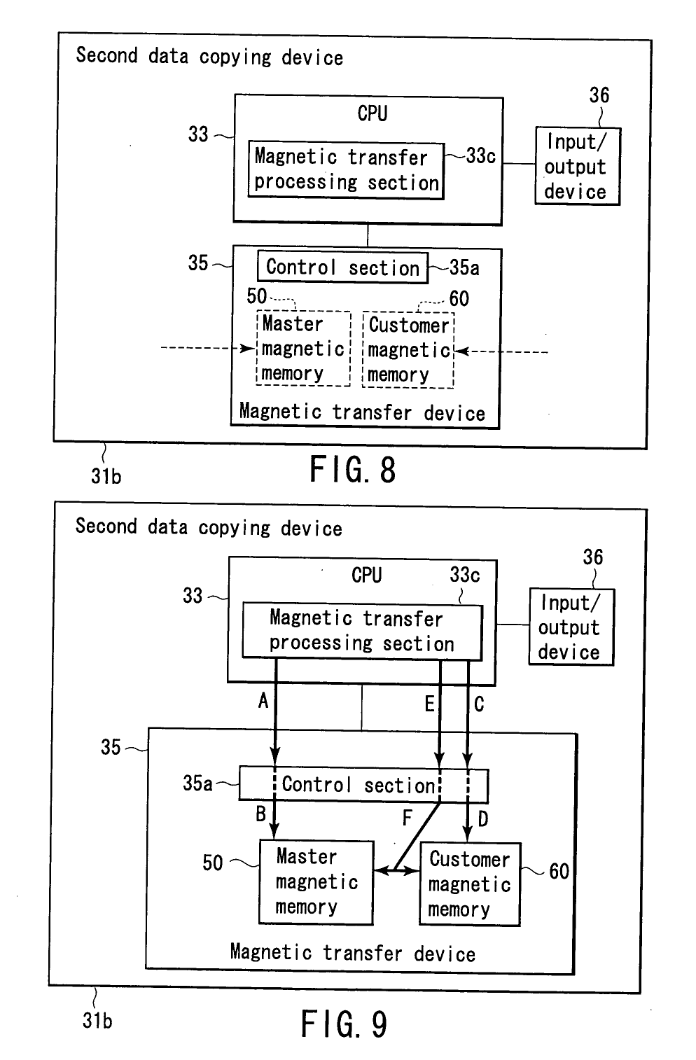

FIGS. 8 and 9 show the configuration and operation of the second data copying device. The configuration of the second data copying device is explained below.

As shown in FIG. 8, a second data copying device 31b includes a CPU 33, magnetic transfer device 35 and input/output device 36.

The CPU 33 includes a magnetic transfer processing section 33c. The magnetic transfer device 35 includes a control section 35a. A master magnetic memory 50 and customer magnetic memory 60 are inserted into the magnetic transfer device 35.

The constituents of the second data copying device 31b have the following functions.

The magnetic transfer processing section 33c has a function of receiving an order from a customer and supplying an instruction used to move the master magnetic memory 50 to a preset copying position to the control section 35a according to the order (instruction A of FIG. 9). Further, it has a function of supplying an instruction used to move the customer magnetic memory 60 to a predetermined copying position to the control section 35a (instruction C of FIG. 9) and a function of supplying an instruction used to copy data of the master magnetic memory 50 into the customer magnetic memory 60 to the control section 35a (instruction E of FIG. 9).

The control section 35a has a function of moving the master magnetic memory 50 to a copying position according to the instruction A (instruction B of FIG. 9) and a function of moving the customer magnetic memory 60 to a copying position according to the instruction C (instruction D of FIG. 9). Further, it has a function of copying data of the master magnetic memory 50 into the customer magnetic memory 60 according to the instruction E (instruction F of FIG. 9). The control section 35a can be omitted.

The input/output device 36 includes a touch panel, for example, and has a function of permitting the user to touch his finger on a button or mark displayed on the display screen so as to input data and output the result of inputting. In this case, the input/output device 36 may be divided into an input device such as a display and an output device such as a keyboard, for example.

Like the first data copying device 31a, in the second data copying device 31b, the communication control device 32, download processing section 33a, storage processing section 33b and memory device 34 may be provided.

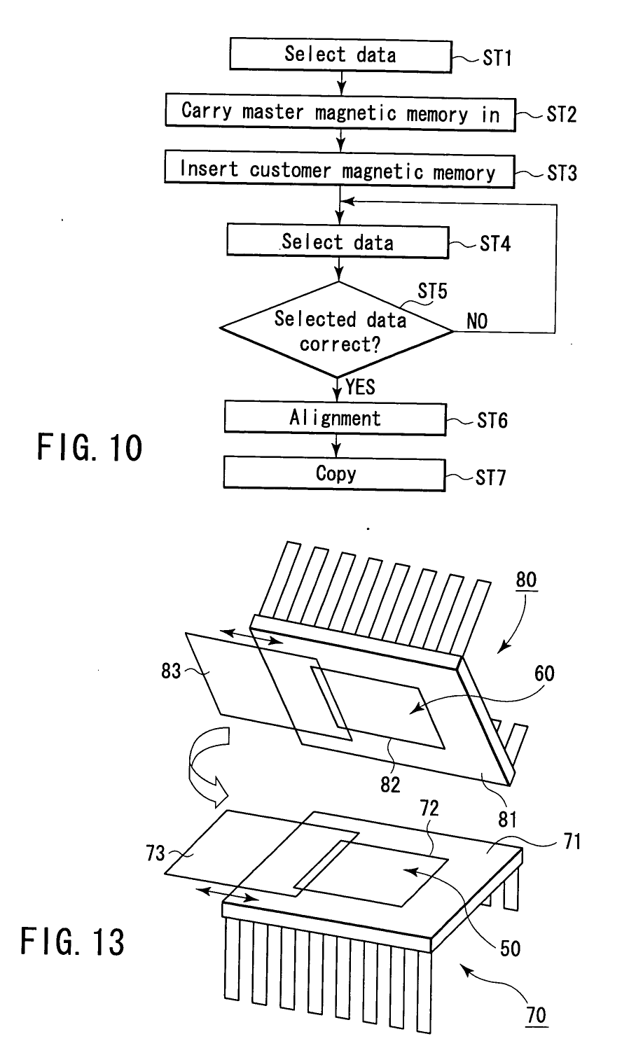

FIG. 10 is a flow diagram showing the second data copying method. The second data copying method is explained below.

First, the manager of the second data copying device 31b selects a plurality of necessary content data items from various content data items (ST1).

Next, the master magnetic memory 50 in which the selected content data is written is carried from the content warehouse into the second data copying device 31b (ST2) and arranged in a preset copying position.

Thus, by performing the steps ST1 and ST2, preparation is completed so as to permit the customer to utilize the data copying device 31b.

Next, the customer inserts the customer magnetic memory 60 into the magnetic transfer device 35 of the second data copying device 31b so as to copy data (ST3).

Then, the customer selects data to be copied from various content data items (ST4).

After this, the selected content data items are displayed on the input/output device 36 in a list form and whether the selected content data items are correct or not is checked (ST5). As a result, if the list of the selected content data items is correct, a screen button “OK” is selected and if it is not correct, a screen button “Correction” is selected.

If the screen button “OK” is selected, the customer magnetic memory 60 is set closer to the master magnetic memory 50 in which the selected data is stored and the master magnetic memory 50 and customer magnetic memory 60 are aligned with each other (ST6). At this time, the two memories are set closer to each other with the free layer of the MTJ element of the master magnetic memory 50 and the free layer of the MTJ element of the customer magnetic memory 60 facing each other. For alignment, an optical method, magnetic method or the like can be used. After completion of the alignment, a screen of “Completion of Alignment” is displayed.

On the other hand, if the screen button “Correction” is selected, the customer selects data to be copied from the various content data items again (ST4).

Then, after the alignment process is completed, the customer selects a screen button of “Start of Copying”. As a result, data of the master magnetic memory 50 is magnetically transferred as one block to the customer magnetic memory 60 (ST7). When the magnetic transferring operation is completed, a screen of “Completion of Copying” is displayed.

At this time, it is desirable to take the ESD measure before the magnetic transferring operation. Further, it is preferable to perform the magnetic transferring operation with the master magnetic memory 50 and customer magnetic memory 60 pressed against each other.

It is necessary to previously write “inverted data” which is inverted data of the reference data into the master magnetic memory 50 in the step ST7 since data is inverted because of the property of the magnetic transferring operation. Thus, the master magnetic memory 50 having the inverted data written therein is carried into the magnetic transfer device 35.

Further, it is necessary to set the coercive force of the master magnetic memory 50 larger than the coercive force of the customer magnetic memory 60 so as to prevent data of the master magnetic memory 50 from being rewritten when data is copied from the master magnetic memory 50 to the customer magnetic memory 60 in the step ST7.

As described above, if the magnetic transferring operation is performed according to the second data copying method by use of the second data copying device, the same effect as that obtained when the first data copying method is used can be attained.

Further, according to the second data transferring method, since it is not necessary to download data and write the same into the master magnetic memory 50, the working load of the manager can be alleviated.

3. Data Copying Program and Recording Medium

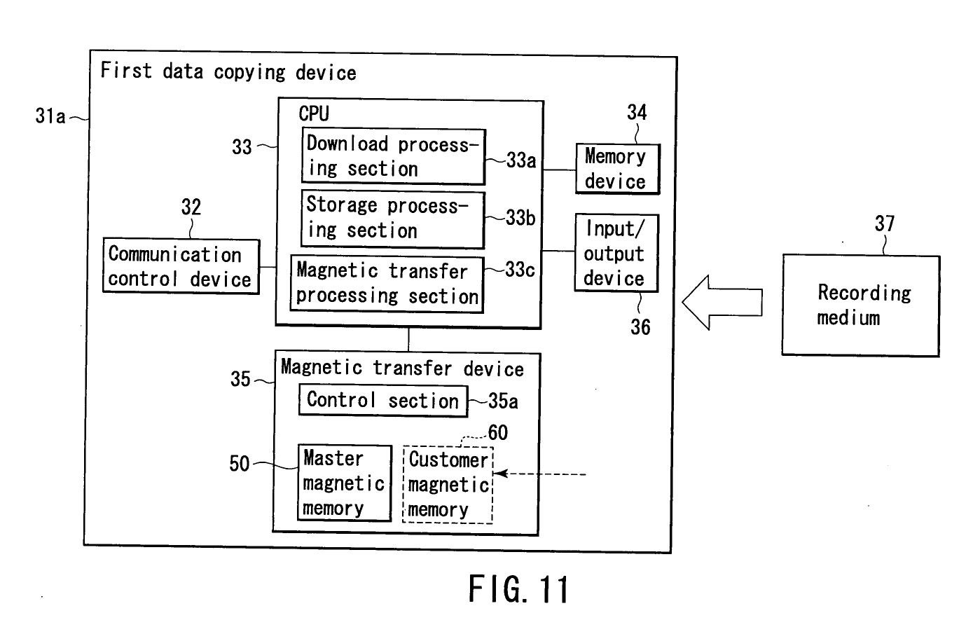

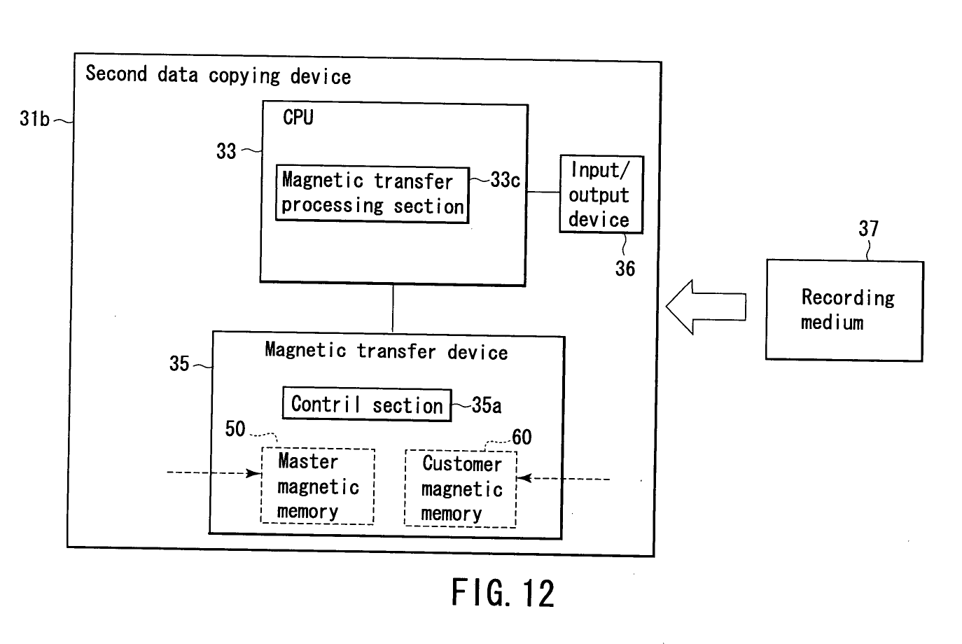

As shown in FIGS. 11 and 12, the first and second data copying devices 31a, 31b can be realized by use of a computer which reads out a program stored in the recording medium 37 such as a magnetic disk, for example, and whose operation is controlled according to the program.

That is, the first and second data copying methods are written into the recording medium 37 as a program executed by the computer. Alternatively, they are transferred as the program via a communication medium. The program can be applied to various devices. The recording medium 37 is a magnetic disk (floppy (registered trademark) disk, hard disk or the like), optical disk (CD-ROM, DVD or the like), semiconductor memory or the like, for example.

The computer which realizes the first and second data copying methods reads out the program recorded in the recording medium 37, the operation thereof is controlled according to the program so that various processes of the first and second data copying methods can be performed.

The program recorded in the recording medium 37 is a program which permits the computer to perform the first and second data copying methods, but it is not always necessary to record the program in the recording medium 37.

4. Package Magnetic Memory:

Like the conventional other semiconductor memories, it is expected that the chip of the magnetic memory is sealed into a package. Therefore, in this example, the structure in which the master magnetic memory 50 and customer magnetic memory 60 are packaged is explained.

(1) Basic Structure:

FIG. 13 is a view showing the basic structure of a packaged magnetic memory.

As shown in FIG. 13, the master magnetic memory 50 is sealed into a package 71 to form a master module 70. An opening portion 72 for magnetic transfer is formed in the surface of the package 71 of the master module 70 and a sliding type cover portion 73 is formed to selectively open and close the opening portion 72.

Likewise, the customer magnetic memory 60 is sealed into a package 81 to form a customer module 80. An opening portion 82 for magnetic transfer is formed in the surface of the package 81 of the customer module 80 and a sliding type cover portion 83 is formed to selectively open and close the opening portion 82.

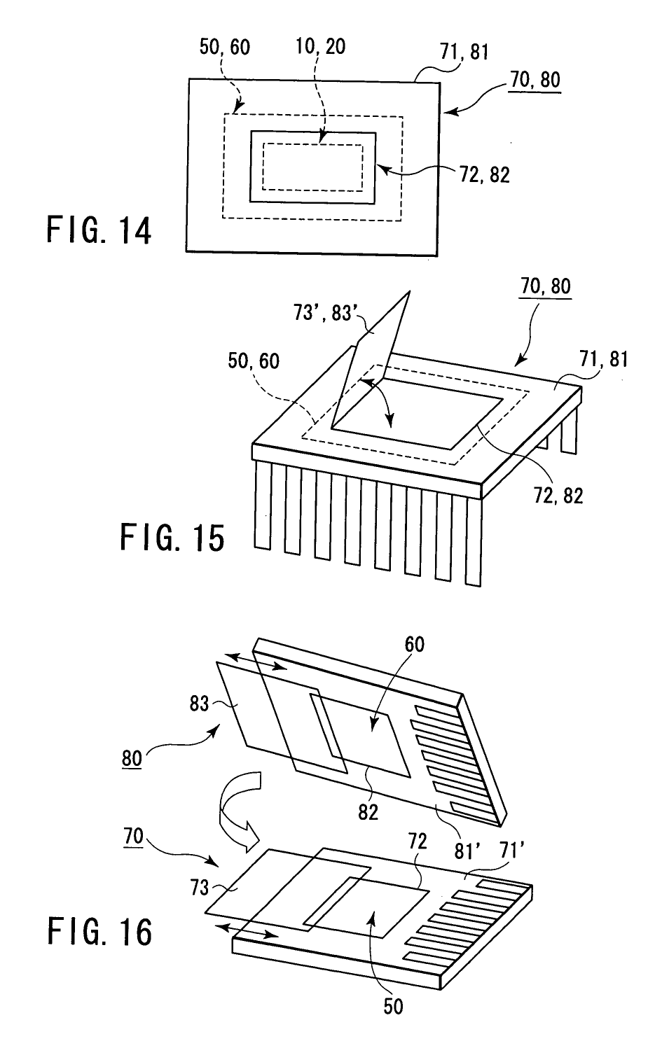

In the master module 70 and customer module 80, the opening portions 72, 82 of the packages 71, 81 are formed larger than the memory sections (MTJ element sections) of at least the master magnetic memory 50 and customer magnetic memory 60 as shown in FIG. 14. Further, it is preferable to form the opening portions 72, 82 of the packages 71, 81 smaller than the surface areas of the master magnetic memory 50 and customer magnetic memory 60.

In order to acquire the high reliability of data, the packages 71, 81 and cover portions 73, 83 may have magnetic shielding roles. To serve this purpose, the packages 71, 81 and cover portions 73, 83 are formed of a magnetically shielding material such as a magnetic metal alloy, for example.

As shown in FIG. 15, the packages 71, 81 may have door-type cover portions 72′, 83′ which selectively open and close the opening portions.

Further, as shown in FIG. 16, the master magnetic memory 50 and customer magnetic memory 60 may be sealed into card-type packages 71′, 81′.

The shapes of the opening portions 72, 82 of the packages 71, 81 and the shapes of the cover portions 73, 83 are not limited to the shapes as shown in the drawing and can be variously changed.

The magnetic transferring process by use of the first and second data copying methods is performed as follows by use of the master magnetic memory 50 and customer magnetic memory 60 which are thus packaged.

In the data copying devices 31a, 31b, the master module 70 in which the master magnetic memory 50 is packaged is received. Then, in the data copying devices 31a, 31b, the customer module 80 in which the customer magnetic memory 60 is packaged is inserted.

The cover portion 83 of the customer module 80 and the cover portion 73 of the master module 70 are made open to expose the memory section (MTJ element section) of the customer magnetic memory 60 and the memory section (MTJ element section) of the master magnetic memory 50.

Then, the memory section of the master magnetic memory 50 and the memory section of the customer magnetic memory 60 are set closer to each other. After this, the magnetic transferring operation is performed by fitting the memory sections on each other to transfer data from the master magnetic memory 50 to the customer magnetic memory 60.

After the magnetic transferring operation, the cover portion 73 of the master module 70 and the cover portion 83 of the customer module 80 are closed to respectively cover the opening portions 72, 82.

In this case, if the magnetic transferring operation is performed as described above, data is inverted at the data transferring time. Therefore, it is necessary to set data written in the master magnetic memory 50 in an inverted form. Further, in order to prevent the magnetization direction of the master magnetic memory 50 from being reversed at the magnetic transferring time, it is necessary to set the coercive force of the master magnetic memory 50 larger than the coercive force of the customer magnetic memory 60.

In the magnetic transferring operation, since data is transferred after the package 71 of the master module 70 and the package 81 of the customer module 80 are aligned with each other, it is necessary to enhance the alignment precision. Therefore, it is preferable to form aligning marks on the packages 71, 81 of the master module 70 and customer module 80.

Further, unlike the customer module 80, the master module 70 is fixed in a specified region (for example, inside the data copying device) and is not carried along in many cases. In such a case, it is not necessary to seal the master magnetic memory 50 into the package 71.

(2) Modification 1:

In the basic structure of the module shown in the item 4(1), the cover portion of the package is opened at the magnetic transferring time and the memory section of the master-magnetic memory 50 and the memory section of the customer magnetic memory 60 are set closer to each other. However, it is preferable to set the memory sections of the two memories as close to each other as possible in order to enhance the precision of the magnetic transferring operation.

Therefore, in the modification 1, in order to set the memory section of the master magnetic memory 50 and the memory section of the customer magnetic memory 60 as close to each other as possible at the magnetic transferring time, the package structures of the master magnetic memory 50 and customer magnetic memory 60 are formed to have concave and convex portions.

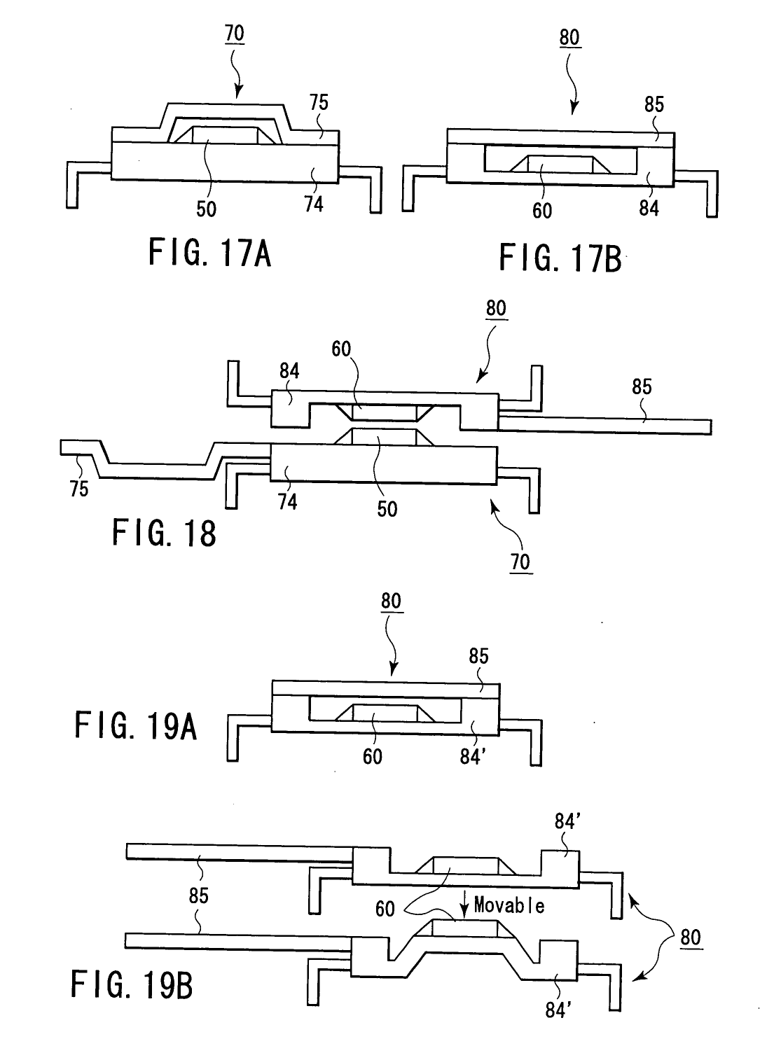

That is, as shown in FIG. 17A, the master magnetic memory 50 is mounted on a flat plate portion 74 in the master module 70 and sealed by use of a cover portion 75 of a convex shape. Therefore, the master magnetic memory 50 will project from the plate portion 74 when the cover portion 75 is opened.

On the other hand, as shown in FIG. 17B, the customer magnetic memory 60 is mounted on a plate portion 84 of a concave shape and sealed by use of a flat cover portion 85. Therefore, the customer magnetic memory 60 is partly received into the plate portion 84 when the cover portion 85 is opened.

With the above package structures, as shown in FIG. 18, the master magnetic memory 50 which projects from the surface of the plate portion 74 comes into the concave portion of the customer magnetic memory 60 which is recessed below the surface of the plate portion 84. Therefore, the memory section of the master magnetic memory 50 and the memory section of the customer magnetic memory 60 can be set extremely close to each other.

The package structures of the master magnetic memory 50 and customer magnetic memory 60 can be exchanged. That is, in the master magnetic memory 50, the structure in which the plate portion 74 is formed in a concave form and the cover portion 75 is formed in a flat form can be used. Further, in the customer magnetic memory 60, the structure in which the plate portion 84 is formed in a flat form and the cover portion 85 is formed in a convex form can be used.

(3) Modification 2:

In the modification 2, in order to set the memory section of the master magnetic memory 50 and the memory section of the customer magnetic memory 60 as close to each other as possible at the magnetic transferring time, the plate portion is vertically movable so that at least one of the master magnetic memory 50 and customer magnetic memory 60 will be projected from the package.

As shown in FIG. 19A, the customer magnetic memory 60 is mounted on a plate portion 84′ of a concave shape in the customer module 80 and sealed by use of a flat cover portion 85. Therefore, the customer magnetic memory 60 is partly received into the plate portion 84′ in the normal state in which the cover portion 85 is closed.

When the cover portion 85 is set in the open state and data is magnetically transferred, as shown in FIG. 19B, the plate portion 84′ is upwardly movable so that the customer magnetic memory 60 will be projected from the plate portion 84′.

After data is magnetically transferred and the cover portion 85 is set in the closed state, the plate portion 84′ is downwardly movable so that the customer magnetic memory 60 will come into the plate portion 84′ and the plate portion 85 can be closed.

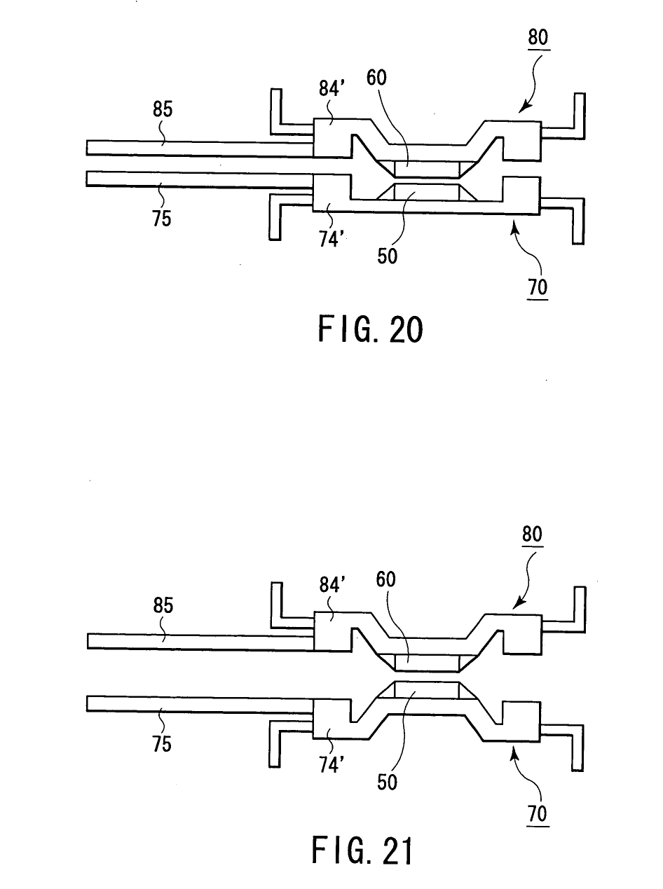

When data is transferred to the customer module 80, for example, when the master module 70 having the plate portion 74 of the concave shape and the flat cover portion 75 is used, as shown in FIG. 20, the plate portion 84′ of the customer module 80 is lifted. As a result, the customer magnetic memory 60 is projected from the surrounding portion of the plate portion 84′ and the projected customer magnetic memory 60 comes into a space of the master module 70 which is recessed below the surface of the plate portion 74. Therefore, the memory section of the master magnetic memory 50 and the memory section of the customer magnetic memory 60 can be set extremely closer to each other.

In this case, the plate portion 74 of the master module 70 may be movable instead of making the plate portion 84′ of the customer module 80 movable.

Further, as shown in FIG. 21, both of the plate potions 74′, 84′ of the customer module 80 and master module 70 can be made movable.

5. Master Magnetic Memory:

In this example, four concrete examples of the structure of the master magnetic memory 50 which performs the magnetic transferring operation are explained.

(1) First Structure:

The first structure is the structure of the master magnetic memory 50 used when the magnetic transferring operation is performed according to the first data copying method.

That is, in the first data copying method, it is necessary to download data via an Internet or the like and write the downloaded data into the master magnetic memory 50. Therefore, the master magnetic memory 50 is required to have the structure which can be set into the write possible state.

In order to serve the above purpose, the first structure has write wirings like the conventional case and the uppermost passivation film or the write wiring of the upper layer is made thin so that the magnetic transferring operation can be easily performed.

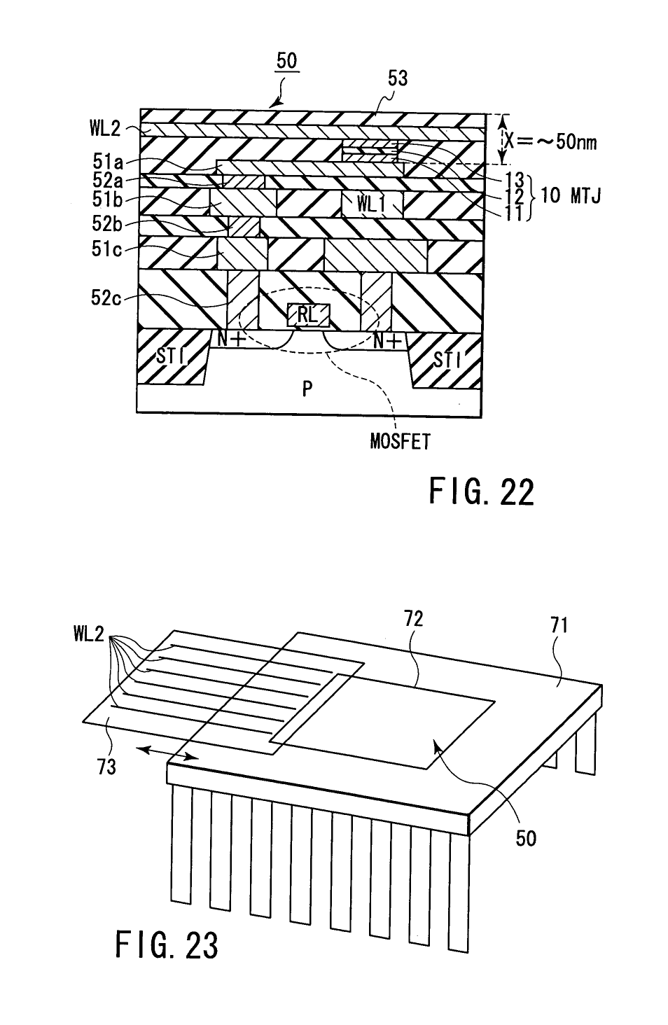

More specifically, as shown in FIG. 22, first write wirings (write word lines) WL1 and second write wirings (read/write bit lines) WL2 are formed to extend in directions perpendicular to each other. MTJ elements 10 are each arranged at the intersection between the first write wiring WL1 and the second write wiring WL2. The MTJ element 10 is connected to a MOSFET which is a readout switching element via a lower metal layer 51a, contacts 52a, 52b, 52c and wirings 51b, 51c. The gate electrode of the MOSFET is used as a read wiring RL (read word line). Further, a passivation film 53 is formed on the second write wiring WL2.

The second write wiring WL2 which is a write wiring of an upper layer is formed thinner than a normal write wiring (for example, the first write wiring WL1). In this case, the first write wiring WL1 is formed with a thickness of approximately 400 nm, for example.

The passivation film 53 which is formed as the uppermost layer of the chip is formed of a DLC (Diamond Like Carbon) film or a thin laminated film of a silicon nitride film and silicon oxide film, for example. The passivation film 53 is formed thinner than the first write wirings WL1.

Further, the MTJ element 10 is formed of the fixed layer 11, free layer (recording layer) 13 and tunnel insulating film 12. It is preferable to arrange the free layer 13 on the front surface side of the chip to make the magnetic transferring operation easy.

With the above first structure, currents are caused to flow in the write wirings WL1, WL2, the resultant magnetic field generated by the currents reverses or does not reverse the magnetization direction of the free layer 13 of the MTJ element 10. Thus, data is written into the MTJ element 10. In this case, data to be written into the MTJ element 10 is inverted data of data which is desired to be stored in the customer magnetic memory 60.

As described above, according to the first structure of the master magnetic memory 50, the following effect can be attained.

In the conventional MRAM structure, as shown in FIG. 45, when the passivation film 94 is formed on the write wiring WL2, the film thickness Y of the passivation film 94 becomes approximately 9000 angstrom since it is formed of a silicon nitride film of 6000 angstrom, a TEOS (Tetra Ethyl Ortho Silicate) film and a ground film. Further, in order to pass a current, the write wiring WL2 is formed with substantially the same thickness as the write wiring WL1. Therefore, since the thick passivation film 94 and thick write wiring WL2 are formed on the MTJ element 90, it is difficult to perform the magnetic transferring operation even if another MTJ element is set closer to the MTJ element 90 in this state.

On the other hand, in the first structure, since the second write wiring WL2 and passivation film 53 are formed thin, a distance X from the chip surface to the surface of the lower metal layer 51a, that is, the total film thickness of the MTJ element 10, second write wiring WL2 and passivation film 53 is equal to or less than 50 nm. Therefore, since the MTJ element 10 is set closer to the chip surface in comparison with a case of the normal MRAM, the magnetic transferring operation can be performed.

The second write wiring WL2 in the first structure is formed to have such thickness as to permit data to be written into the MTJ element 10 of the master magnetic memory 50. Further, the coercive force of the master magnetic memory 50 is set larger than that of the customer magnetic memory 60.

(2) Second Structure:

Like the first structure, the second structure is the structure of the master magnetic memory 50 used when the magnetic transferring operation is performed according to the first data copying method. Further, the second structure is the structure obtained when the master magnetic memory 50 is sealed into a package.

In order to more easily perform the magnetic transferring operation than in the first structure, in the second structure, the upper-layer write wiring WL2 is not formed on the master magnetic memory 50 side, but is formed on the cover portion side of the package.

More specifically, as shown in FIG. 23, the master magnetic memory 50 is sealed into a package 71 having an opening portion 72 formed therein and a sliding type cover portion 73 is formed on the opening portion 72. The write wirings WL2 are formed on the cover portion 73.

As shown in FIG. 24, the write wiring WL2 is formed to lie above the MTJ element 10 and the write wiring WL1 is formed below the MTJ element 10. Like the first structure, a passivation film (for example, a DLC film) 53 which is thinner than the write wiring WL1 is formed on the MTJ element 10. Therefore, a distance X from the chip surface to the surface of the lower metal layer 51a, that is, the total film thickness of the MTJ element 10 and passivation film 53 is equal to or less than 50 nm.

In this case, as shown in FIG. 14, the opening portion 72 of the package 71 is formed larger than at least the memory portion (MTJ element 10 portion) of the master magnetic memory 50. Further, it is preferable to form the opening portion 72 of the package 71 smaller than the surface area of the master magnetic memory 50.

Further, in order to acquire the high reliability of data, it is preferable that the package 71 and cover portion 73 have a magnetically shielding role. Therefore, the package 71 and cover portion 73 is formed of a magnetically shielding material such as a magnetic metal alloy, for example.

In this case, the package 71 may be formed of a door-type cover portion 73′ which is selectively set into the closed the open positions as shown in FIG. 15.

In the second structure, when downloaded data is written into the master magnetic memory 50, the cover portion 73 of the package 71 is set into the closed state and the MTJ element 10 is disposed between the two write wirings WL1 and WL2. Then, currents are caused to flow in the write wirings WL1, WL2 and the magnetization direction of the free layer 13 of the MTJ element 10 is reversed or is not reversed by the resultant magnetic field generated by the currents. As a result, data is written into the MTJ element 10. In this case, data to be written into the MTJ element 10 is inverted data of data which is desired to be stored in the customer magnetic memory 60.

On the other hand, when data written in the MTJ element 10 is magnetically transferred to the customer magnetic memory 60, the cover portion 73 of the package 71 is set into the open state. Thus, the write wirings WL2 are removed from above the MTJ elements 10 and the magnetic transferring operation can be easily performed.

As described above, according to the second structure, it is not necessary to form the write wirings WL2 on the MTJ elements 10 of the master magnetic memory 50 by forming the write wirings WL2 on the cover portion 73 of the package 71. Therefore, in the second structure, since the MTJ element 10 is set closer to the chip surface by a distance corresponding to the thickness of the write wirings WL2 in comparison with the case of the first structure, the magnetic transferring efficiency can be further enhanced.

Further, since the cover portion 73 having the write wirings WL2 is set into the open state at the magnetic transferring time, the write wirings WL2 are removed from above the MTJ elements 10 at the magnetic transferring time. Therefore, it is not necessary to form the write wiring WL2 as thin as that in the first structure and the write wiring WL2 can be formed with substantially the same thickness as the write wiring WL1. Therefore, when data is written into the master magnetic memory 50, a write current larger than that in the case of the first structure can be caused to flow through the write wiring WL2.

In the second structure, it is necessary to pay much attention to the device design, for example, it is necessary to provide alignment marks on the package so as to precisely align the write wiring WL2 with the MTJ element 10.

(3) Third Structure:

The third structure is the structure of the master magnetic memory 50 used when the magnetic transferring operation is performed according to the second data copying method.

That is, in the second data copying method, data is not downloaded via Internet or the like and data is previously written at the time of formation of the master magnetic memory 50. Therefore, when the master magnetic memory 50 is mounted on the data copying device, it is not necessary to provide write wirings which are required at the write time on the master magnetic memory 50.

In the third structure, after a normal MRAM is formed at the time of formation of the master magnetic memory 50 and data is written into the master magnetic memory 50, the write wirings WL2 of the uppermost layer are removed to form the memory in a ROM form. In this case, data to be written into the MTJ element 10 is inverted data of data which is desired to be stored in the customer magnetic memory 60.

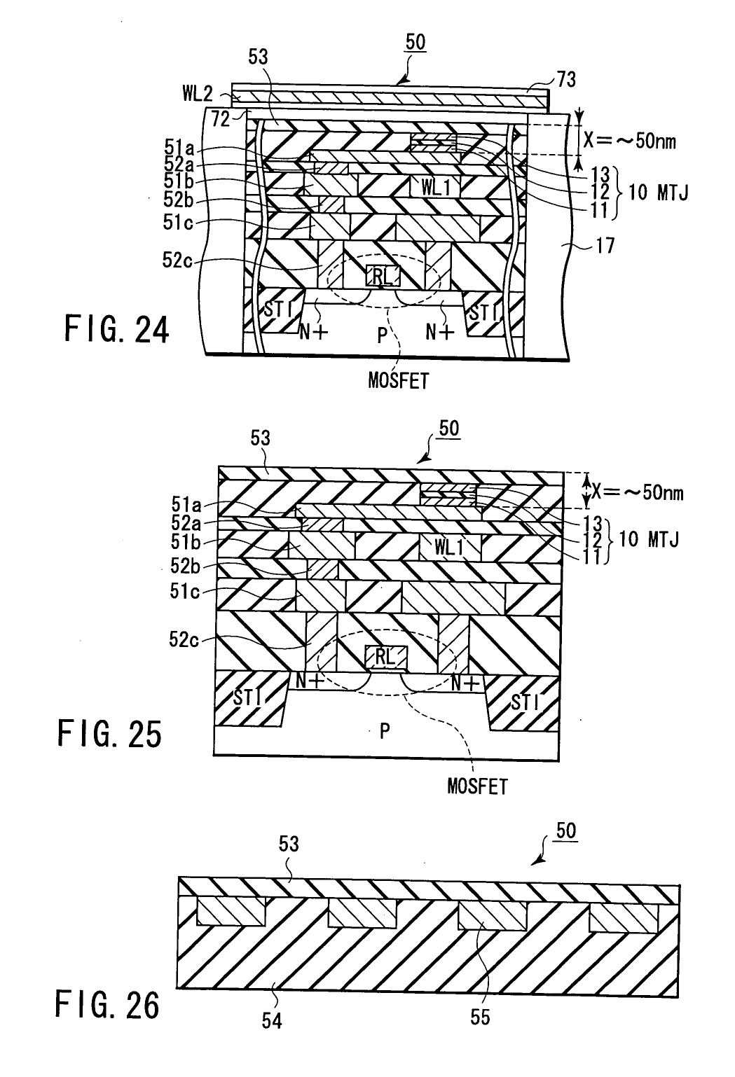

More specifically, as shown in FIG. 25, since a passivation film (for example, a DLC film) 53 which is thinner than the write wiring WL1 is formed on the MTJ element 10 after the write wirings WL2 of the uppermost layer are removed, only the passivation film 53 exists on the MTJ element 10. Further, the write wirings WL1 are left behind below the MTJ element 10.

Since the passivation film 53 is made thin, the distance X from the chip surface to the surface of the lower metal layer 51a, that is, the total film thickness of the MTJ element 10 and passivation film 53 is equal to or less than 50 nm.

As described above, according to the third structure, the write wirings WL2 of the upper layer are removed after data is written into the master magnetic memory 50, and therefore, the write wirings WL2 do not exist at the magnetic transferring time. Thus, in the third structure, since the MTJ element 10 is set closer to the chip surface in comparison with the first structure, the magnetic transferring efficiency can be further enhanced.

Further, since the write wirings WL2 are removed before the magnetic transferring operation, it is not necessary to form the write wiring WL2 as thin as that in the first structure and the write wiring WL2 can be formed with substantially the same thickness as the write wiring WL1. Therefore, when data is written into the master magnetic memory 50, a write current larger than in the case of the first structure can be caused to flow through the write wiring WL2.

(4) Fourth Structure:

Like the third structure, the fourth structure is the structure of the master magnetic memory 50 used when the magnetic transferring operation is performed according to the second data copying method.

That is, in the fourth structure, the master magnetic memory 50 is formed in a ROM form, wirings and elements which are required for writing and reading are not provided and magnetic films in which data is written are arranged.

More specifically, as shown in FIG. 26, a plurality of magnetic films 55 are formed in an interlaid insulating film 54 such as a TEOS film or FSG (Fluorine Spin Glass) film, for example, and a thin passivation film (for example, a DLC film) 53 is formed on the magnetic films 55. Then, data is written by selectively magnetizing the magnetic films 55. The write operation is performed directly with respect to the magnetic films 55 by excitation of direct drawing or optical excitation by use of a mask. Data to be written into the MTJ element 10 is inverted data of data which is desired to be stored in the customer magnetic memory 60.

Like the fixed layer 11 and free layer 13 of the MTJ element 10, the magnetic film 55 is formed of a magnetic material such as NiFe, for example. The material of the MTJ element 10 is described later.

As described above, according to the fourth structure, since the magnetic transferring operation is performed by use of the magnetic films 55 in which data is written, the write wirings and the like do not exist on the magnetic films 55. Therefore, in the fourth structure, since the MTJ element 10 is set closer to the chip surface in comparison with the first structure, the magnetic transferring efficiency can be further enhanced.

There is a possibility that it takes a longer time to write data into the magnetic film 55 in comparison with the writing operation by use of a magnetic field caused by a current in the MRAM, but since the operation is not performed on the customer side, it will not give a bad influence on a reduction in the transferring time.

6. Customer Magnetic Memory:

(1) Structure of Customer Magnetic Memory:

In this example, a concrete example of the structure of the customer magnetic memory 60 which performs the magnetic transferring operation is explained.

In the customer magnetic memory 60, the data writing operation is performed by magnetic transferring data from the master magnetic memory 50. Therefore, it is not necessary to provide the write wirings or the like on the customer magnetic memory 60. As a result, the customer magnetic memory 60 is formed with the structure which can perform at least the data readout operation.

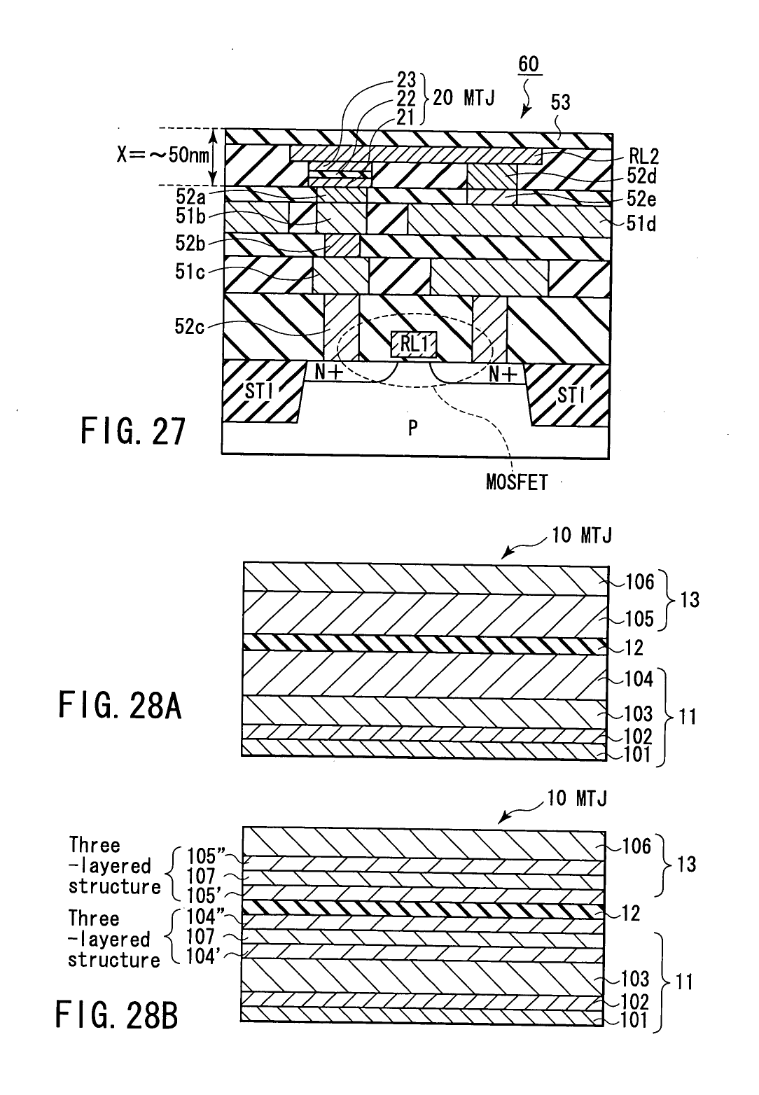

More specifically, as shown in FIG. 27, an MTJ element 20 is connected to a MOSFET which is a switching element for reading via contacts 52a, 52b, 52c and wirings 51b, 51c. The gate electrode of the MOSFET is used as a readout wiring RL1. A readout wiring RL2 with a single layer is formed on the MTJ element 20 and a passivation film (for example, a DLC film) 53 is formed on the readout wiring RL2. Further, contacts 52d, 52e and wiring 51d are formed under and below the readout wiring RL2, a sense amplifier (not shown) or the like is connected to the wiring 51d and data can be read out.

In this case, a distance X from the undersurface of the MTJ element 20 to the surface of the passivation film, that is, the total film thickness X of the MTJ element 20, readout wiring RL2 and passivation film 53 is extremely small. This is because the transferring operation cannot be performed if the distance X is not shorter when the magnetic transferring operation is performed. In the present situation, it is preferable to set the distance X equal to or less than 50 nm.

The wiring 51d which lies below the readout wiring RL2 is formed as thick as the normal wiring and formed thicker than the readout wiring RL2.

As described above, in the structure of the customer magnetic memory 60, no write wirings exist above and below the MTJ element 20 and only the readout wiring RL is formed so that the MTJ element 20 can be set closer to the chip surface than in the normal MRAM. Thus, the structure which can perform the magnetic transferring operation is attained. Inverted data of the MTJ element 10 of the master magnetic memory 50 is magnetically transferred to the MTJ element 20 of the customer magnetic memory 60.

In the customer magnetic memory 60, the write wirings may be provided if the magnetic transferring operation can be performed.

Further, the customer magnetic memory 60 is not limited to the structure shown in FIG. 27. For example, the first to third structures of the master magnetic memory 50 described above can be applied not only to the master magnetic memory 50 but also to the customer magnetic memory 60. However, in this case, it is necessary to adjust a difference between the coercive forces of the master magnetic memory 50 and the customer magnetic memory 60 so as to make the coercive force of the master magnetic memory 50 larger than that of the customer magnetic memory 60.

(2) Application of Magnetically Transferring Time to Customer Magnetic Memory:

As described above, the magnetic transferring operation from the master magnetic memory 50 to the customer magnetic memory 60 is performed by use of the first data copying device 31a shown in FIG. 4 or the second data copying device 31b shown in FIG. 8. In the magnetic transferring operation, the customer magnetic memory 60 which is completed to the final structure and set in a packaged form is used.

However, the magnetic transferring operation from the master magnetic memory 50 to the customer magnetic memory 60 may be performed in the course of the manufacturing process of the customer magnetic memory 60.

That is, after the MTJ element 20 is patterned and the surrounding portion of the MTJ element 20 is buried with an insulating film in the customer magnetic memory 60, the master magnetic memory 50 is set closer thereto and the magnetic transferring operation may be performed. Then, after data has been written into the customer magnetic memory 60 by the magnetic transferring operation, the contact 52d, readout wiring RL2 and passivation film 53 are formed and the customer magnetic memory 60 having data written therein is sold to a customer.

As described above, when the magnetic transferring operation is performed in the course of manufacturing of the customer magnetic memory 60 (after formation of the MTJ element), the MTJ element 20 can be set closer to the master magnetic memory 50. Therefore, the magnetic transferring operation with respect to the customer magnetic memory 60 can be easily performed in comparison with a case wherein the magnetic transferring operation is performed after the memory is completed to the final structure.

When the magnetic transferring operation is performed in the course of manufacturing of the customer magnetic memory 60, the first and second data copying devices 31a, 31b are not used.

7. MTJ Element:

Next, the structure of the MTJ element is explained.

The MTJ element 10 has a three-layered structure which includes a magnetically fixed layer (magnetic pinning layer; magnetic layer) 11 whose magnetization direction is fixed, a tunnel insulating film (non-magnetic layer) 12 and a free layer (magnetic layer) 13 whose magnetization direction can be reversed.

The MTJ element 10 is formed in a rectangular shape, for example. The easy axis of magnetization is set in the lengthwise direction of the rectangular shape and the hard axis of magnetization is set in a direction perpendicular to the lengthwise direction thereof. In order to reverse the magnetization direction at the data writing time, the easy axis of magnetization of the MTJ element 10 is set in a direction perpendicular to the extending direction of the write wirings through which a current can be passed in both directions so as to change the direction of the current according to write data.

For example, in the master magnetic memory 50 of FIG. 22, it is assumed that the write wiring through which a write current can be passed in both directions is the second write wiring WL2. Then, the easy axis of magnetization of the MTJ element 10 is set in a direction perpendicular to the extending direction of the second write wiring WL2, that is, in the extending direction of the first write wiring WL1.

The MTJ element 10 may have a single tunnel junction structure having a single-layered tunnel insulating film 12 or a double tunnel junction structure having a double-layered tunnel insulating film 12.

Next, an example of the MTJ element 10 of the single tunnel junction structure or double tunnel junction structure is explained.

(1) Single Tunnel Junction Structure:

The MTJ element 10 of the single tunnel junction structure shown in FIG. 28A includes a fixed layer 11 which has a ground contact layer (ground electrode layer) 101, buffer layer (for example, ferromagnetic layer) 102, anti-ferromagnetic layer 103 and ferromagnetic layer 104 stacked in this order, a tunnel insulating film 12 formed on the fixed layer 11 and a free layer 13 having a free ferromagnetic layer 105 and contact layer 106 stacked in this order on the tunnel insulating film 12.

The MTJ element 10 of the single tunnel junction structure shown in FIG. 28B includes a fixed layer 11 which has a ground contact layer 101, buffer layer 102, anti-ferromagnetic layer 103, ferromagnetic layer 104′, non-magnetic layer 107 and ferromagnetic layer 104″ stacked in this order, a tunnel insulating film 12 formed on the fixed layer 11 and a free layer 13 having a ferromagnetic layer 105′, non-magnetic layer 107, ferromagnetic layer 105″ and contact layer 106 stacked in this order on the tunnel insulating film 12.

In the MTJ element 10 shown in FIG. 28B, the three-layered structure of the ferromagnetic layer 104′, non-magnetic layer 107 and ferromagnetic layer 104″ in the fixed layer 11 and the three-layered structure of the ferromagnetic layer 105′, non-magnetic layer 107, ferromagnetic layer 105″ in the free layer 13 are formed. Thus, a cell structure which more effectively suppresses generation of magnetic poles in the internal portion of the ferromagnetic body and is more suitable for miniaturization in comparison with the MTJ element 10 shown in FIG. 28A can be provided.

(2) Double Tunnel Junction Structure:

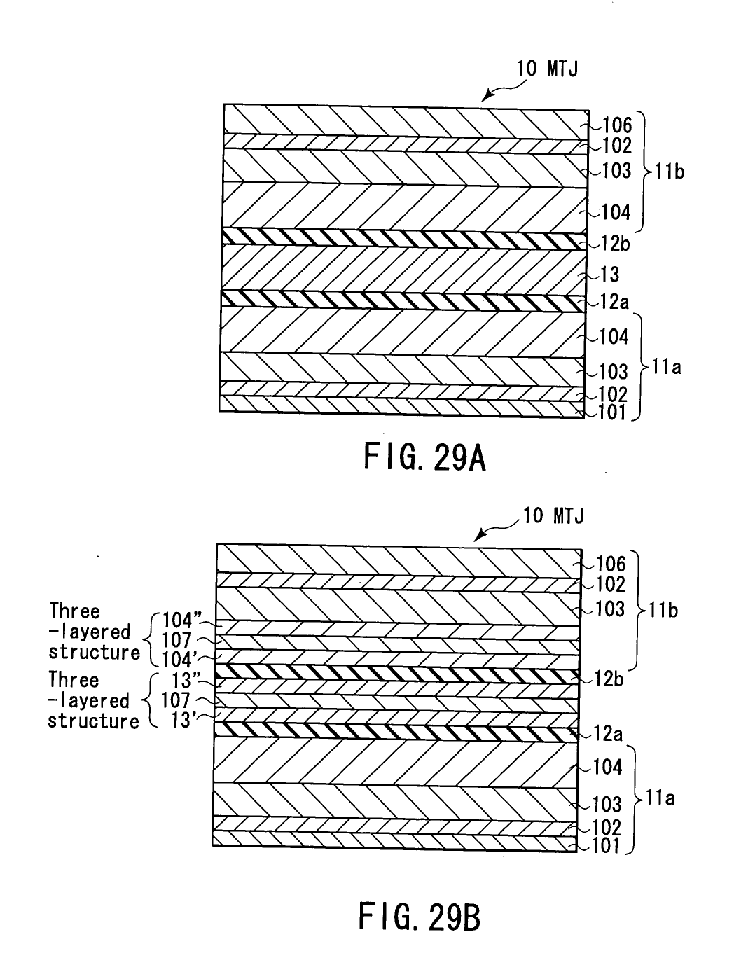

The MTJ element 10 of the double tunnel junction structure shown in FIG. 29A includes a first fixed layer 11a which has a ground contact layer 101, buffer layer 102, anti-ferromagnetic layer 103 and ferro-magnetic layer 104 stacked in this order, a first tunnel insulating film 12a formed on the first fixed layer 11a, a free layer 13 formed on the first tunnel insulating film 12a, a second tunnel insulating film 12b formed on the free layer 13, and a second fixed layer 11b having a ferromagnetic layer 104, anti-ferromagnetic layer 103, buffer layer 102 and contact layer 106 stacked in this order on the second tunnel insulating film 12b.

The MTJ element 10 of the double tunnel junction structure shown in FIG. 29B includes a first fixed layer 11a which has a ground contact layer 101, buffer layer 102, anti-ferromagnetic layer 103 and ferromagnetic layer 104 stacked in this order, a first tunnel insulating film 12a formed on the first fixed layer 11a, a free layer 13 having a three-layered structure of a ferromagnetic layer 13′, non-magnetic layer 107 and ferromagnetic layer 13″ stacked in this order on the first tunnel insulating film 12a, a second tunnel insulating film 12b formed on the free layer 13, and a second fixed layer 11b having a ferromagnetic layer 104′, non-magnetic layer 107, ferromagnetic layer 104″, anti-ferromagnetic layer 103, buffer layer 102 and contact layer 106 stacked in this order on the second tunnel insulating film 12b.

In the MTJ element 10 shown in FIG. 29B, the three-layered structure of the ferromagnetic layer 13′, non-magnetic layer 107 and ferromagnetic layer 13″ configuring the free layer 13 and the three-layered structure of the ferromagnetic layer 104′, non-magnetic layer 107, ferromagnetic layer 104″ in the second fixed layer 11b are formed. Thus, a cell structure which more effectively suppresses generation of magnetic poles in the internal portion of the ferromagnetic body and is more suitable for miniaturization in comparison with the MTJ element 10 shown in FIG. 29A can be provided.

In the MTJ element 10 of the double tunnel junction structure, a deterioration in the MR (Magneto Resistive) ratio (a variation rate of the resistance between the “1” state and “0” state) when the same external bias is applied thereto becomes less than that in a case of the MTJ element 10 of the single tunnel junction structure. Thus, it can be operated on the higher bias. That is, the double tunnel junction structure is advantageous when information of the cell is read out.

(3) Material of MTJ Element:

The MTJ element 10 of the single or double tunnel junction structure is formed of the following material, for example.

As the materials of the fixed layers 11, 11a, 11b and free layer 13, for example, it is preferable to use Fe, Co, Ni or the alloy thereof, magnetite having high spin polarizability, oxide such as CO₂, RXMnO_{3-y} (R: rare earth material, X: Ca, Ba, Sr), a Heuslar alloy such as NiMnSb, PtMnSb or the like. Further, the magnetic materials may contain a small amount of non-magnetic element such as Ag, Cu, Au, Al, Mg, Si, Bi, Ta, B, C, O, N, Pd, Pt, Zr, Ir, W, Mo, Nb if the ferromagnetic property thereof can be maintained.

As a material of the anti-ferromagnetic layer 103 which configures part of the fixed layers 11, 11a, 11b, it is preferable to use Fe—Mn, Pt—Mn, Pt—Cr—Mn, Ni—Mn, Ir—Mn, NiO, Fe₂O₃ or the like.

As the material of the tunnel insulating films 12, 12a, 12b, various dielectric materials such as Al₂O₃, SiO₂, MgO, AlN, Bi₂O₃, MgF₂, CaF₂, SrTiO₂, AlLaO₃ can be used. Oxygen, nitrogen, fluorine defective may exist in the above dielectric materials.

The material of the fixed layer 11 and free layer 13 of the MTJ element 10 described above can be used as the material of the magnetic film 55 which is explained in the fourth structure (refer to FIG. 24) of the master magnetic memory 50.

(4) Difference between MTJ Elements of Master Magnetic Memory and Customer Magnetic Memory:

In the above items 7(1) to 7(3), the MTJ element 10 of the master magnetic memory 50 is explained as an example, but the explanation can be applied to the MTJ element 20 of the customer magnetic memory 60.

However, the coercive force of the master magnetic memory 50 must be larger than the coercive force of the customer magnetic memory 60. This is because the magnetization direction of the free layer 23 of the MTJ element 20 of the customer magnetic memory 60 can be reversed with respect to the magnetization direction of the free layer 13 of the MTJ element 10 of the master magnetic memory 50. Thus, the magnetic transferring operation, that is, the data writing operation can be performed by setting the coercive force of the master magnetic memory 50 larger than the coercive force of the customer magnetic memory 60 as is explained in the principle of the magnetic transferring operation.

Therefore, for example, it is preferable to provide the following difference between the structures of the MTJ elements 10, 20 of the master magnetic memory 50 and customer magnetic memory 60 in order to set the coercive force of the master magnetic memory 50 larger than the coercive force of the customer magnetic memory 60.

For example, the surface area of the MTJ element 10 of the master magnetic memory 50 may be set larger than the surface area of the MTJ element 20 of the customer magnetic memory 60.

Further, the aspect ratio of the MTJ element 10 of the master magnetic memory 50 may be set larger than the aspect ratio of the MTJ element 20 of the customer magnetic memory 60. In this case, the aspect ratio is a ratio of the lengths of the surface areas of the MTJ elements 10, 20 in the easy axis and hard axis of magnetization.

In addition, the film thickness of the free layer 13 of the MTJ element 10 of the master magnetic memory 50 may be set larger than the film thickness of the free layer 23 of the MTJ element 20 of the customer magnetic memory 60.

(5) Positional Relation between MTJ Elements of Master Magnetic Memory and Customer Magnetic Memory:

In this example, the positional relation between the MTJ element 10 of the master magnetic memory 50 and MTJ elements 20a, 20b, 20c of the customer magnetic memory 60 at the magnetic transferring time is explained.

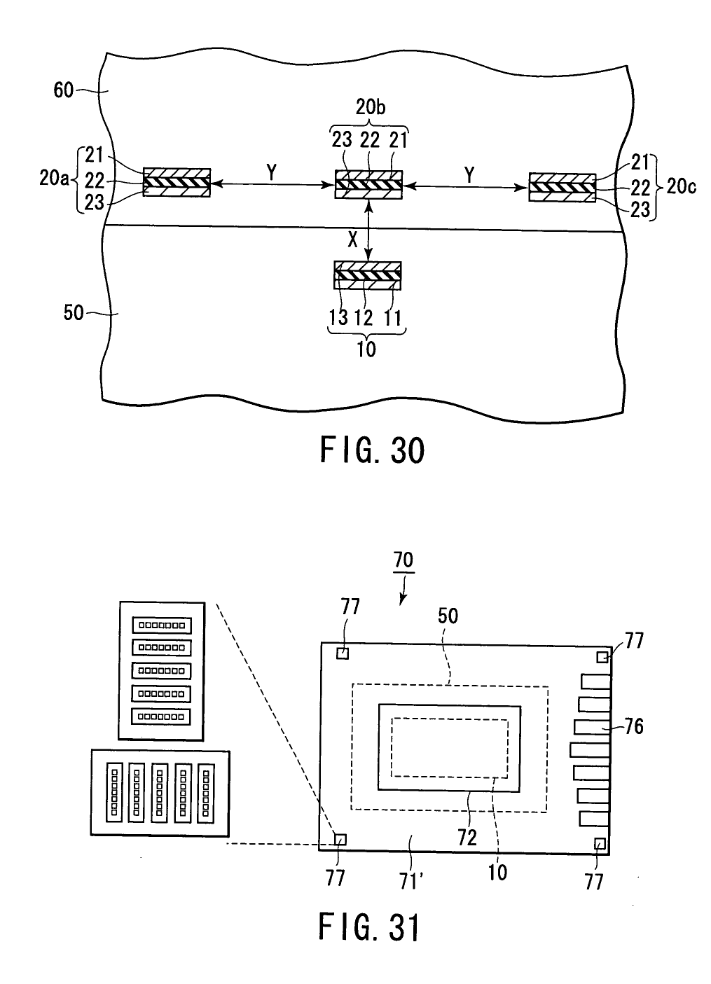

As shown in FIG. 30, for example, it is assumed that the MTJ element 10 is provided in the master magnetic memory 50 and the MTJ elements 20a, 20b, 20c are provided in the customer magnetic memory 60. When data of the MTJ element 10 of the master magnetic memory 50 is transferred to the MTJ element 20b of the customer magnetic memory 60, it is preferable to set up the positional relation which satisfies the relation expressed by the following equation (1).

X≦½Y (1)

where X denotes a distance between the MTJ element 10 and the MTJ element 20b and Y denotes a distance between the MTJ element 20a and the MTJ element 20b and a distance between the MTJ element 20a and the MTJ element 20c.

Thus, it is preferable to separate the MTJ elements 20a, 20b, 20c of the customer magnetic memory 60 apart from one another by a distance which is equal to or larger than twice the distance X with respect to the MTJ element 10. The reason is to suppress data from being erroneously transferred to the MTJ element 20a, 20c which are adjacent to the MTJ element 20b when data is magnetically transferred to the MTJ element 20b.

8. Alignment Marks for Master Magnetic Memory and Customer Magnetic Memory:

As described above, the aligning process is performed before data of the master magnetic memory 50 is magnetically transferred to the customer magnetic memory 60. In the aligning process, the master magnetic memory 50 and customer magnetic memory 60 are set closer to each other with the free layer 13 of the MTJ element 10 of the master magnetic memory 50 and the free layer 23 of the MTJ element 20 of the customer magnetic memory 60 facing each other. In order to perform the precise aligning process, the following aligning mark technique may be used.

In this case, an example in which the master magnetic memory 50 and customer magnetic memory 60 are received in a card-type package is explained. However, the package is not limited to the card-type package.

(1) First Aligning Mark Example:

The first aligning mark example is to set aligning marks on packages in which the master magnetic memory 50 and customer magnetic memory 60 are received.

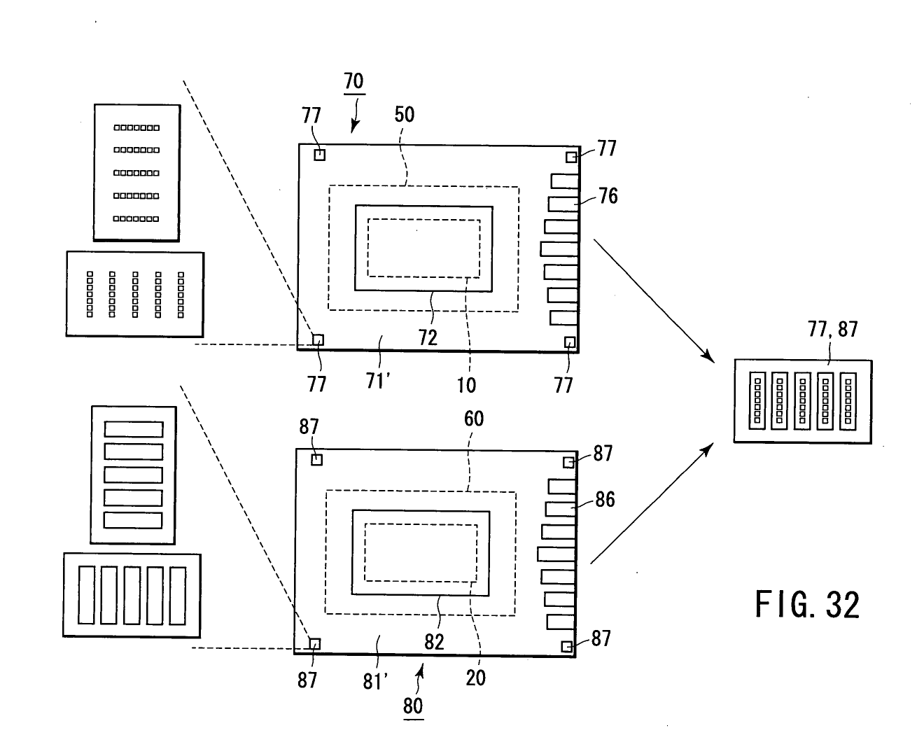

As shown in FIG. 31, aligning marks 77 which are similar to lithography marks are set on the corner portions of an outer frame of a package 71′ in which the master magnetic memory 50 is sealed. The aligning marks 77 are marks in XY directions and can be provided in any region of the outer frame of the package 71′ if possible, and the number of aligning marks is not limited. Likewise, aligning marks are set on a package in which the customer magnetic memory 60 is received (refer to FIG. 32).

As shown in FIG. 32, in the case of the first aligning mark example, one of the package 71′ of a master module 70 and a package 81′ of a customer module 80 is made transparent so as to check an alignment error when they are overlapped.

According to the first aligning mark example, the aligned position can be checked over a large area and the aligned position can be checked even when the cover portion 73 is set in the closed state. However, since the magnetic memory is indirectly aligned with the package mark, the aligning precision is slightly lowered in comparison with a case of a second aligning mark example which will be described later.

(2) Second Aligning Mark Example:

The second aligning mark example is to set aligning marks on chips of the master magnetic memory 50 and customer magnetic memory 60. In this case, the master module 70 is explained as an example, but the customer module 80 has the same structure.

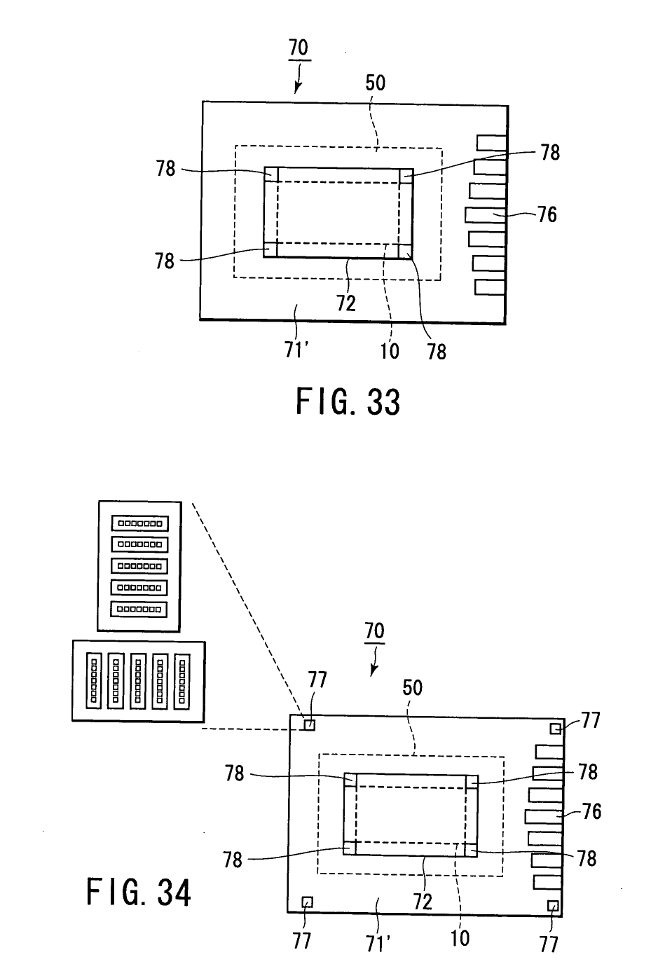

As shown in FIG. 33, aligning marks 78 of a magnetic sensor are set on the corner portions of the memory section (MTJ element 10) of the master magnetic memory 50. The aligning marks 78 can be provided in any region in the outer periphery of the memory section if possible, and the number of aligning marks is not limited. Further, the aligning marks 78 are simultaneously formed in the same hierarchical layer as the MTJ element 10 and are formed of the same material as the MTJ element.

In the case of the second aligning mark example, the directions of the magnetization of the master magnetic memory 50 and customer magnetic memory 60 are sensed and the aligned position thereof is checked.

According to the second aligning mark example, the aligning mark 78 and the MTJ element 10 can be directly aligned with each other by forming the aligning mark 78 and the MTJ element 10 of the chip in the same step. Therefore, the aligning precision is extremely high. However, the time of checking the aligned position is limited to the time of opening of the cover portion of the chip and the closely attached time and the serviceability thereof is slightly lowered in comparison with a case of the first aligning mark example.

(3) Third Aligning Mark Example:

The third aligning mark example is a combination of the first and second aligning mark examples and is to set aligning marks on the packages in which the master magnetic memory 50 and customer magnetic memory 60 are received and on the chips of the master magnetic memory 50 and customer magnetic memory 60. In this case, the master module 70 is explained as an example, but the customer module 80 has the same structure.

As shown in FIG. 34, aligning marks 77 which are similar to lithography marks are set on the corner portions of an outer frame of a package 71′ in which the master magnetic memory 50 is sealed. Further, aligning marks 78 of a magnetic sensor are set on the corner portions of the memory section (MTJ element 10) of the master magnetic memory 50. The detail portions of the above aligning marks are similar to those of the examples of the first and second aligning marks.

In the case of the third aligning mark example, the position is roughly aligned by use of the aligning marks 77 on the package and is then precisely aligned by use of the aligning marks 78 on the chip.

According to the third aligning mark example, both of the roughly aligned position and the precisely aligned position can be checked. In this case, however, there occurs a problem that the number of aligning steps is increased.

(4) Relation between Aligning Marks and Lid Portion:

In the first to third aligning mark examples, the following relation between the aligning mark and the cover portion is attained. In this case, an example in which the third aligning mark example is used is explained, but the example is not limitative.

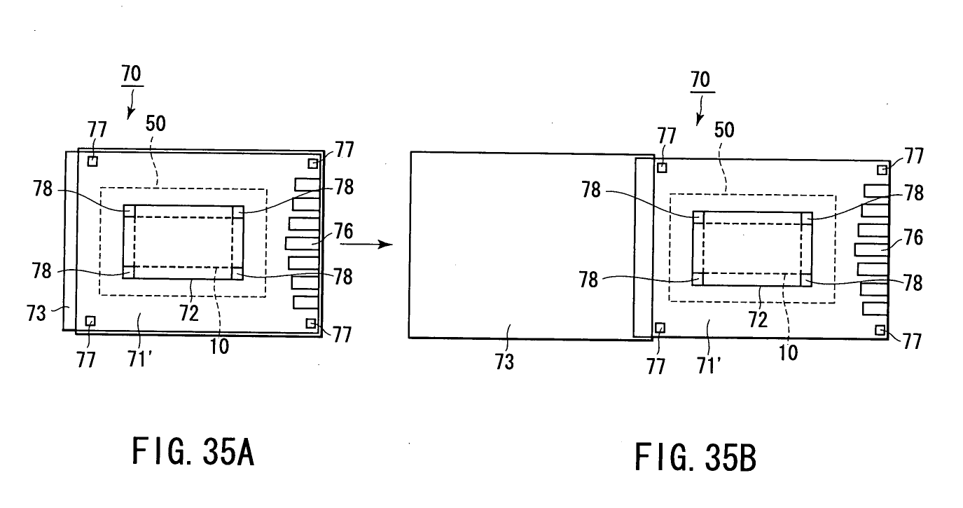

When the cover portion 73 is set in the closed state, as shown in FIG. 35A, the aligning marks 77, 78 are covered with the cover portion 73. On the other hand, when the cover portion 73 is set in the open state, as shown in FIG. 35B, the aligning marks 77, 78 are exposed to the exterior.

When the cover portion 73 is set in the closed state, it is preferable to cover the aligning marks 78 on the chip and memory section (MTJ element 10) with the cover portion 73, but it is not always necessary to cover the aligning marks 77 on the package 71′ with the cover portion 73.

9. Structure of Magnetic Transfer Device:

In this example, the structure of the magnetic transfer device 35 of the data copying devices 31a, 31b is explained.

In this case, the structure of the magnetic transfer device 35 into or on which the customer module 80 is inserted, fitted or slid and inserted is explained. However, the structure of the magnetic transfer device 35 can be modified so that the master module 70 may be inserted into, fitted on or slid and inserted into the magnetic transfer device 35 in the same manner.

(1) Inserting Type:

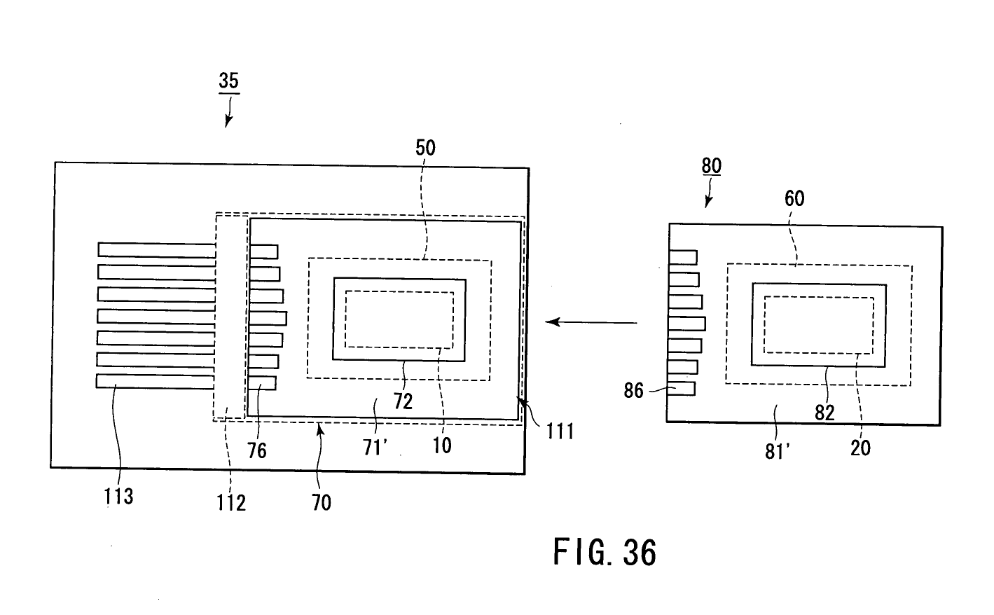

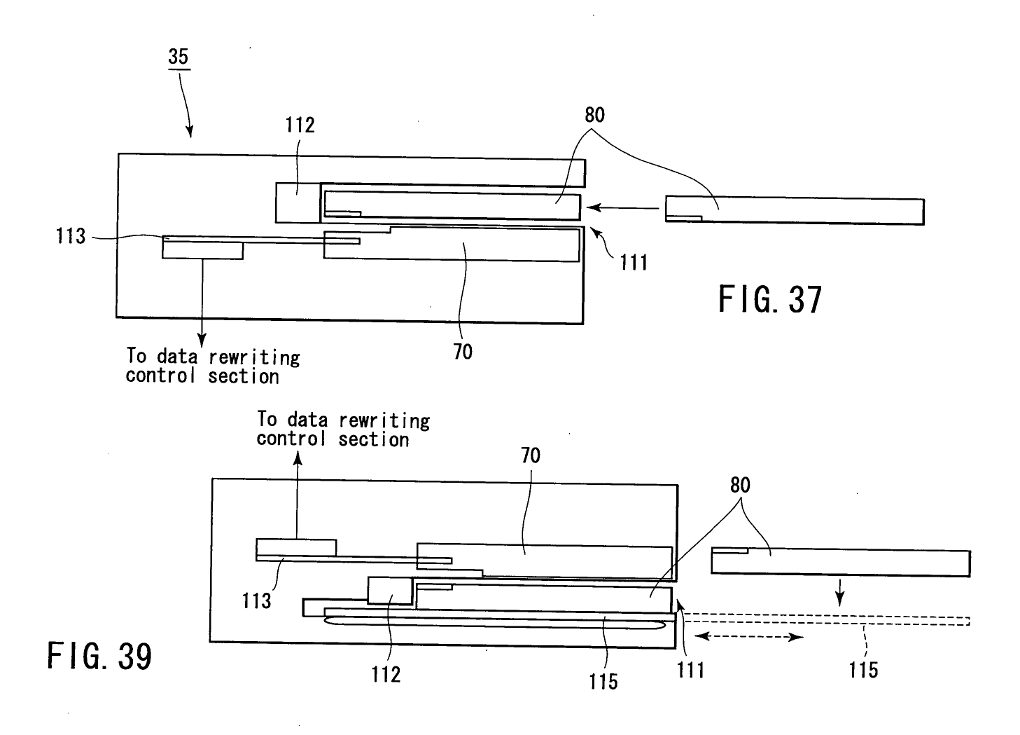

FIGS. 36, 37 show the inserting type magnetic transfer device 35. As shown in FIGS. 36, 37, the magnetic transfer device 35 is formed to have an inserting portion 111 into which the customer module 80 is inserted and a stopper portion 112 used to set the customer module 80 in a specified position for alignment. The master module 70 is provided in the magnetic transfer device 35 and data of the master module 70 can be rewritten by use of external terminals 76, 113.

In the case of the inserting type, the customer module 80 is inserted into the magnetic transfer device 35 via the inserting portion 111 and pushed into the magnetic transfer device 35 until it is stopped by the stopper portion 112. When the master module 80 is placed in the specified position, data stored in the master module 70 is transferred to the customer module 80.

(2) Fitting Type:

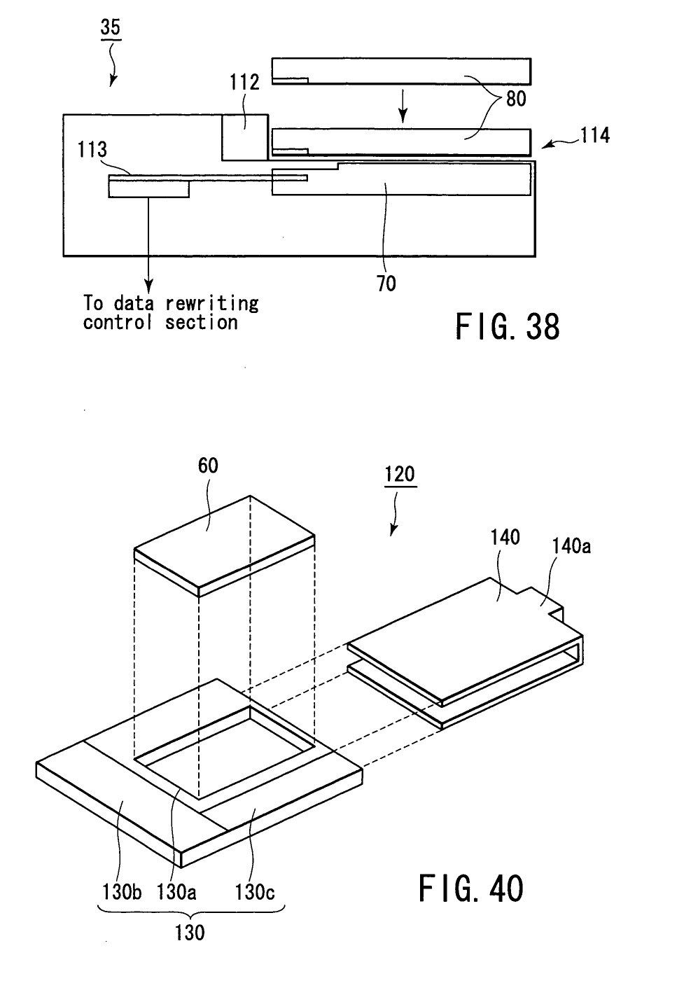

FIG. 38 shows the fitting type magnetic transfer device 35. As shown in FIG. 38, the magnetic transfer device 35 is formed to have a fitting portion 114 on which the customer module 80 is fitted and a stopper portion 112 used to set the customer module 80 in a specified position for alignment.

In the case of the fitting type, the customer module 80 is fitted on the fitting portion 114 with the stopper 112 used as a target. When the master module 80 is disposed in the specified position, data stored in the master module 70 is transferred to the customer module 80.

(3) Sliding-Inserting Type:

FIG. 39 shows the sliding-inserting type magnetic transfer device 35. As shown in FIG. 39, like the CD-ROM drive, DVD drive or the like, the magnetic transfer device 35 is formed to have a sliding type receiving plate portion 115. The sliding type receiving plate portion 115 is operated so as to be inserted into or removed from the inserting portion 111 as indicated by an arrow in FIG. 39.

In the case of the sliding-inserting type, the receiving plate 115 is slid and removed from the inserting portion 111 and the customer module 80 is placed on the receiving plate portion 115. After this, when the master module 80 is inserted into the magnetic transfer device 35 via the inserting portion 111 and slid into the magnetic transfer device 35 until the customer module 80 is stopped by the stopper portion 112. When the master module 80 is thus placed in the specified position, data stored in the master module 70 is transferred to the customer module 80.

10. Magnetic Memory Cartridge and Drive Device:

In this example, a magnetic memory cartridge in which the customer magnetic memory 60 is received and a drive device are explained.

FIG. 40 shows the magnetic memory cartridge. As shown in FIG. 40, a magnetic memory cartridge 120 is used to receive the customer magnetic memory 60 which stores content information such as an image, music and the like. The magnetic memory cartridge 120 includes a case 130 and shutter 140.

The case 130 includes a concave portion 130a on which the customer magnetic memory 60 is placed, a shutter guide 130b used as a guide when the shutter 140 is closed or opened, and a stopper 130c used to determine the position of the shutter 140 when it is set in the closed state. Further, for example, the case 130 is formed of a material obtained by mixing a magnetic material such as MFe₂O₄ (M=Mn, Fe, Co, Ni, Cu, Mg, for example) with epoxy mould resin.

The shutter 140 selectively closes or opens the concave portion 130a when it is mounted on the case 130. The shutter 140 has a convex portion used as an engaging portion 140a. Further, the shutter 140 has an elastic member (not shown) such as a spring in the internal portion thereof. Therefore, the shutter 140 is automatically returned from the open state to the closed state by the action of the elastic member when it is mounted on the case 130. The shutter is formed of a material having a magnetically shielding effect.

Like the customer magnetic memory 60, the master magnetic memory 50 can be received into the cartridge.

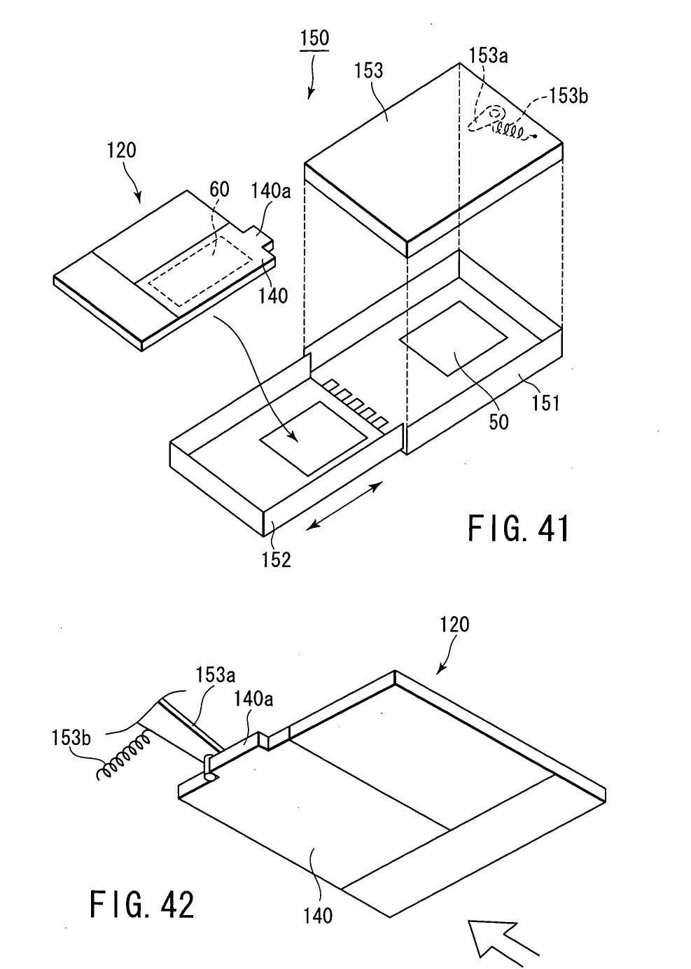

FIG. 41 shows the drive device. As shown in FIG. 41, a drive device 150 includes a tray body portion 151, a tray sliding portion 152 which slides to be received into the tray body portion 151, and a tray cover portion 153 which covers the tray body portion 151.

The master magnetic memory 50 is placed on the tray body portion 151. Further, a magnetic memory cartridge 120 having the customer magnetic memory 60 received therein is mounted on the tray sliding portion 152. On the internal surface of the tray cover portion 153, an opening lever 153a and spring 153b are provided.

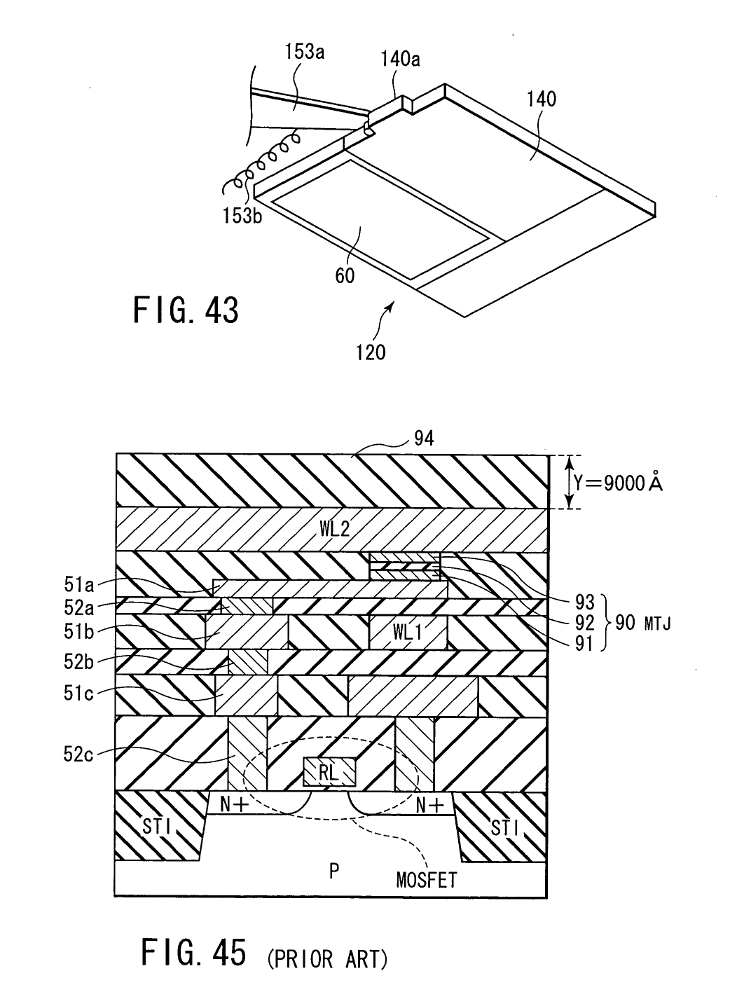

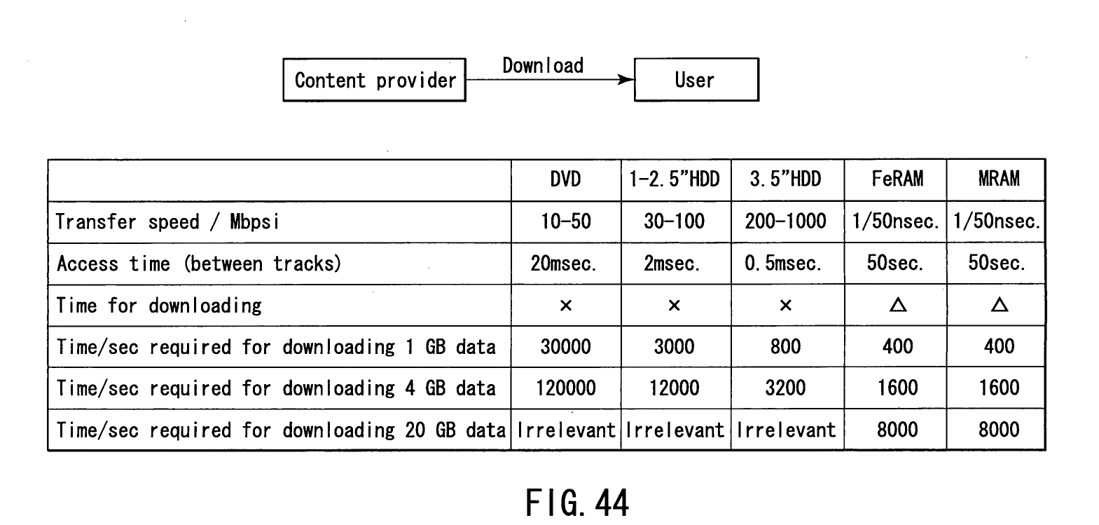

The following magnetic transferring operation is performed by use of the drive device 150. First, the magnetic memory cartridge 120 is mounted on the tray sliding portion 152 and the tray sliding portion 152 is inserted into the tray body portion 151. As a result, one end portion of the opening lever 153a of the tray cover portion 153 is engaged with the engaging portion 140a of the shutter 140 (refer to FIG. 42) to set the shutter 140 of the magnetic memory cartridge 120 into the open state (refer to FIG. 43).

The spring 153b has a function of restoring the opening lever 153a to the original position when the magnetic memory cartridge 120 is removed from the drive device 150.

11. Others:

In addition, the embodiment of the present invention is not limited to the above embodiments and can be variously modified without departing from the technical scope thereof when it is embodied.

(1) The readout switching element is not limited to the MOSFET. For example, the readout switching element can be formed of a MIS (Metal Insulator Semiconductor) transistor (including a MOS transistor), MES (Metal Semiconductor) transistor, junction transistor, bipolar transistor, diode or the like.

(2) The master magnetic memory and customer magnetic memory are not limited to the above structures. That is, if a structure in which the MTJ element is set closer to the uppermost surface of the chip is used, the arrangement of write wirings and read wirings may be variously modified and the readout switching element can be omitted.

(3) The magneto-resistance element is not limited to the MTJ element. For example, as the magneto-resistance element, a GMR (Giant Magneto-Resistance) element having two magnetic layers and a conductive layer sandwiched between the magnetic layers and a CMR (Colossal Magneto-Resistance) element having perovskite type Mn oxide can be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A magnetic memory device comprising:
a first write wiring formed to extend in a first direction,
a first magneto-resistance element arranged above the first write wiring, and
a passivation film formed thinner than the first write wiring and disposed on the first magneto-resistance element.

2. The magnetic memory device according to claim 1, wherein the passivation film is a DLC (Diamond Like Carbon) film.

3. The magnetic memory device according to claim 1, wherein a total film thickness of the first magneto-resistance element and the passivation film is not larger than 50 nm.

4. The magnetic memory device according to claim 1, wherein the first magneto-resistance element is an MTJ element which includes at least a first fixed layer, a first free layer and a first tunnel insulating film sandwiched between the first fixed layer and the first free layer.

5. The magnetic memory device according to claim 4, wherein the first free layer is formed in contact with the passivation film.

6. The magnetic memory device according to claim 1, further comprising a second write wiring formed between the first magneto-resistance element and the passivation film to extend in a second direction different from the first direction.

7. The magnetic memory device according to claim 6, wherein the passivation film is a DLC film.

8. The magnetic memory device according to claim 6, wherein the second write wiring is thinner than the first write wiring.

9. The magnetic memory device according to claim 6, wherein a total film thickness of the first magneto-resistance element, the second write wiring and the passivation film is not larger than 50 nm.

10. The magnetic memory device according to claim 1, further comprising:
a first package having a first opening portion formed in a position above the first magneto-resistance element,
a first cover portion which selectively opens and closes the first opening portion, and
a second write wiring formed in the first cover portion and arranged above the first magneto-resistance element when the first cover portion is set in a closed state.

11. The magnetic memory device according to claim 10, wherein the passivation film is a DLC film.

12. The magnetic memory device according to claim 10, wherein a total film thickness of the first magneto-resistance element and the passivation film is not larger than 50 nm.

13. The magnetic memory device according to claim 10, wherein the first cover portion is of a sliding type to be selectively set into open and closed states.

14. The magnetic memory device according to claim 10, wherein the first cover portion is of a door-type to be selectively set into open and closed states.

15. The magnetic memory device according to claim 10, wherein the first package is formed of a magnetically shielding material.

16. The magnetic memory device according to claim 10, wherein the first cover portion is formed of a magnetically shielding material.

17. The magnetic memory device according to claim 10, further comprising a first mark portion for alignment provided on the first package.

18. The magnetic memory device according to claim 10, wherein the first cover portion is opened at the magnetic transferring time.

19. A magnetic memory device comprising:
a first write wiring formed to extend in a first direction,
a first magneto-resistance element arranged above the first write wiring, and
a passivation film formed of a DLC film on the first magneto-resistance element.

20. The magnetic memory device according to claim 19, wherein a total film thickness of the first magneto-resistance element and the passivation film is not larger than 50 nm.

21. The magnetic memory device according to claim 19, wherein the first magneto-resistance element is an MTJ element which includes at least a first fixed layer, a first free layer and a first tunnel insulating film sandwiched between the first fixed layer and the first free layer.

22. The magnetic memory device according to claim 21, wherein the first free layer is formed in contact with the passivation film.

23. The magnetic memory device according to claim 19, further comprising a second write wiring formed between the first magneto-resistance element and the passivation film to extend in a second direction different from the first direction.

24. The magnetic memory device according to claim 23, wherein the second write wiring is thinner than the first write wiring.

25. The magnetic memory device according to claim 23, wherein a total film thickness of the first magneto-resistance element, the second write wiring and the passivation film is not larger than 50 nm.

26. The magnetic memory device according to claim 19, further comprising:
a first package having a first opening portion formed in a position above the first magneto-resistance element,
a first cover portion which selectively opens and closes the first opening portion, and
a second write wiring formed in the first cover portion and arranged above the first magneto-resistance element when the first cover portion is set in a closed state.

27. The magnetic memory device according to claim 26, wherein a total film thickness of the first magneto-resistance element and the passivation film is not larger than 50 nm.

28. The magnetic memory device according to claim 26, wherein the first cover portion is of a sliding type to be selectively set into open and closed states.

29. The magnetic memory device according to claim 26, wherein the first cover portion is of a door type to be selectively set into open and closed states.

30. The magnetic memory device according to claim 26, wherein the first package is formed of a magnetically shielding material.

31. The magnetic memory device according to claim 26, wherein the first cover portion is formed of a magnetically shielding material.

32. The magnetic memory device according to claim 26, further comprising a first mark portion for alignment provided on the first package.

33. The magnetic memory device according to claim 26, wherein the first cover portion is opened at the magnetic transferring time.

34. A magnetic memory device comprising:
a first magneto-resistance element,
a first read wiring formed on the first magneto-resistance element,
a passivation film formed on the first read wiring, and
a second read wiring connected to the first read wiring, disposed below the first read wiring and formed thicker than the first read wiring.

35. The magnetic memory device according to claim 34, wherein a total film thickness of the first magneto-resistance element, the first read wiring and the passivation film is not larger than 50 nm.

36. The magnetic memory device according to claim 34, wherein the passivation film is formed of a DLC film.

37. A magnetic memory device comprising:
a first write wiring formed to extend in a first direction,
a first magneto-resistance element arranged above the first write wiring,
a passivation film formed thinner than the first write wiring and disposed on the first magneto-resistance element,
a first package in which a chip containing the first write wiring, the first magneto-resistance element and the passivation film are sealed, and in which a first opening portion is formed to expose the chip, and
a first cover portion which selectively opens and closes the first opening portion.

38. A magnetic memory device comprising:
a first magneto-resistance element,
a first read wiring formed on the first magneto-resistance element,
a passivation film formed on the first read wiring,
a second read wiring connected to the first read wiring, disposed below the first read wiring and formed thicker than the first read wiring,
a first package in which a chip containing the first magneto-resistance element, the first and second read wirings and the passivation film are sealed, and in which a first opening portion is formed to expose the chip, and
a first cover portion which selectively opens and closes the first opening portion.

39. A magnetic memory device comprising:
a first write wiring formed to extend in a first direction,
a first magneto-resistance element arranged above the first write wiring,
a passivation film formed thinner than the first write wiring and disposed on the first magneto-resistance element,
a first plate portion of a flat shape which is arranged a chip containing the first write wiring, the first magneto-resistance element and the passivation film, and
a first cover portion of a convex shape formed to cover the chip.

40. A magnetic memory device comprising:
a first magneto-resistance element,
a first read wiring formed on the first magneto-resistance element,
a passivation film formed on the first read wiring,
a second read wiring connected to the first read wiring, disposed below the first read wiring and formed thicker than the first read wiring,
a first plate portion of a flat shape which is arranged a chip containing the first magneto-resistance element, the first and second read wirings and the passivation film, and
a first cover portion of a convex shape formed to cover the chip.

41. A magnetic memory device comprising:
a first write wiring formed to extend in a first direction,
a first magneto-resistance element arranged above the first write wiring,
a passivation film formed thinner than the first write wiring and disposed on the first magneto-resistance element,
a first plate portion of a concave shape which is arranged a chip containing the first write wiring, the first magneto-resistance element and the passivation film, and
a first cover portion of a flat shape formed to cover the chip.

42. A magnetic memory device comprising:
a first magneto-resistance element,
a first read wiring formed on the first magneto-resistance element,
a passivation film formed on the first read wiring,
a second read wiring connected to the first read wiring, disposed below the first read wiring and formed thicker than the first read wiring,
a first plate portion of a concave shape which is arranged a chip containing the first magneto-resistance element, the first and second read wirings and the passivation film, and
a first cover portion of a flat shape formed to cover the chip.

43. A magnetic memory device comprising:
a first write wiring formed to extend in a first direction,
a first magneto-resistance element arranged above the first write wiring,
a passivation film formed thinner than the first write wiring and disposed on the first magneto-resistance element,
a first movable plate portion which is arranged a chip containing the first write wiring, the first magneto-resistance element and the passivation film and which is moved to lift the chip, and
a first cover portion of a flat shape formed to cover the chip.

44. A magnetic memory device comprising:
a first magneto-resistance element,
a first read wiring formed on the first magneto-resistance element,
a passivation film formed on the first read wiring,
a second read wiring connected to the first read wiring, disposed below the first read wiring and formed thicker than the first read wiring,
a first movable plate portion which is arranged a chip containing the first magneto-resistance element, the first and second read wirings and the passivation film and which is moved to lift the chip, and
a first cover portion of a flat shape formed to cover the chip.

45. A data copying device comprising:
a magnetic transfer processing section which magnetically transfers first data of a first magnetic memory to a second magnetic memory and writes second data into the second magnetic memory, and
an input/output section which inputs and outputs an instruction of the magnetic transfer processing section.

46. The data copying device according to claim 45, further comprising a control section which controls the first and second magnetic memories according to the instruction.

47. The data copying device according to claim 45, further comprising:
a communication control section which connects the data copying device to a network,
a download processing section which downloads the first data by use of the communication control section, and
a storage processing section which writes the downloaded first data into the first magnetic memory.

48. The data copying device according to claim 47, further comprising a memory section into which the downloaded first data is written before the downloaded first data is written into the first magnetic memory.

49. The data copying device according to claim 47, wherein the first data is inverted data of the second data.

50. The data copying device according to claim 47, wherein the first magnetic memory has coercive force larger than the second magnetic memory.

51. The data copying device according to claim 50, wherein the first magnetic memory includes a first magneto-resistance element, the second magnetic memory includes a second magneto-resistance element and a surface area of the first magneto-resistance element is larger than a surface area of the second magneto-resistance element.

52. The data copying device according to claim 50, wherein the first magnetic memory includes a first magneto-resistance element, the second magnetic memory includes a second magneto-resistance element and an aspect ratio of the first magneto-resistance element is larger than an aspect ratio of the second magneto-resistance element.

53. The data copying device according to claim 50, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and a film thickness of the first free layer is larger than a film thickness of the second free layer.

54. The data copying device according to claim 47, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and the first and second free layers are set close to each other by use of the control section with the first and second free layers facing each other at the magnetic transferring time.

55. A data copying system comprising:
a data copying device, and
a server connected to the data copying device via a network and having a database,
wherein the data copying device includes
a communication control section which connects the data copying device to the server,
a download processing section which downloads first data from the database by use of the communication control section,
a storage processing section which writes the first data into a first magnetic memory,
a magnetic transfer processing section which magnetically transfers the first data written into the first magnetic memory to a second magnetic memory and writes second data into the second magnetic memory, and
an input/output section which inputs and outputs instructions of the communication control section, the download processing section, the storage processing section and the magnetic transfer processing section.

56. The data copying system according to claim 55, further comprising a control section which writes the first data into the first magnetic memory according to an instruction of the storage processing section and writes the second data into the second magnetic memory by magnetic transferring according to an instruction of the magnetic transfer processing section.

57. The data copying system according to claim 55, wherein the data copying device further includes a memory section into which the downloaded first data is written before the downloaded first data is written into the first magnetic memory.

58. The data copying system according to claim 55, wherein the first data is inverted data of the second data.

59. The data copying system according to claim 55, wherein the first magnetic memory has larger coercive force than the second magnetic memory.

60. The data copying system according to claim 59, wherein the first magnetic memory includes a first magneto-resistance element, the second magnetic memory includes a second magneto-resistance element and a surface area of the first magneto-resistance element is larger than a surface area of the second magneto-resistance element.

61. The data copying system according to claim 59, wherein the first magnetic memory includes a first magneto-resistance element, the second magnetic memory includes a second magneto-resistance element and an aspect ratio of the first magneto-resistance element is larger than an aspect ratio of the second magneto-resistance element.

62. The data copying system according to claim 59, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and a film thickness of the first free layer is larger than a film thickness of the second free layer.

63. The data copying system according to claim 59, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and the first and second free layers are set close to each other by use of the control section with the first and second free layers facing each other at the magnetic transferring time.

64. A recording medium which stores a data copying program readable by a computer, the data copying program causing the computer to execute a process, the process comprising:
connecting a data copying device to a server via a network,
selecting first data from a database of the server,
downloading the first data into the data copying device,
writing the downloaded first data into a first magnetic memory,
setting a second magnetic memory in the data copying device, and
setting the first and second magnetic memories close to each other to magnetically transfer the first data to the second magnetic memory and write second data into the second magnetic memory.

65. A recording medium which stores a data copying program readable by a computer, the data copying program causing the computer to execute a process, the process comprising:
setting a first magnetic memory written first data in a data copying device,
setting a second magnetic memory in the data copying device, and
setting the first and second magnetic memories close to each other to magnetically transfer the first data to the second magnetic memory and write second data into the second magnetic memory.

66. The recording medium according to claim 64, wherein the first data is inverted data of the second data.

67. The recording medium according to claim 64, wherein the first magnetic memory has larger coercive force than the second magnetic memory.

68. The recording medium according to claim 64, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and a magnetic transferring operation is performed while the first and second free layers are being set close to each other with the first and second free layers facing each other.

69. A data copying method comprising:
connecting a data copying device to a server via a network,
selecting first data from a database of the server,
downloading the first data into the data copying device,
writing the downloaded first data into a first magnetic memory,
setting a second magnetic memory in the data copying device, and
setting the first and second magnetic memories close to each other to magnetically transfer the first data to the second magnetic memory and write second data into the second magnetic memory.

70. The data copying method according to claim 69, further comprising writing the first data into a memory section of the data copying device before the first data is written into the first magnetic memory.

71. A data copying method comprising:
setting a first magnetic memory written first data in a data copying device,
setting a second magnetic memory in the data copying device, and
setting the first and second magnetic memories close to each other to magnetically transfer the first data to the second magnetic memory and write second data into the second magnetic memory.

72. The data copying method according to claim 69, wherein the first data is inverted data of the second data.

73. The data copying method according to claim 69, wherein the first magnetic memory has larger coercive force than the second magnetic memory.

74. The data copying method according to claim 73, wherein the first magnetic memory includes a first magneto-resistance element, the second magnetic memory includes a second magneto-resistance element and a surface area of the first magneto-resistance element is larger than a surface area of the second magneto-resistance element.

75. The data copying method according to claim 73, wherein the first magnetic memory includes a first magneto-resistance element, the second magnetic memory includes a second magneto-resistance element and an aspect ratio of the first magneto-resistance element is larger than an aspect ratio of the second magneto-resistance element.

76. The data copying method according to claim 73, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and a film thickness of the first free layer is larger than a film thickness of the second free layer.

77. The data copying method according to claim 69, wherein the first magnetic memory includes a first magneto-resistance element which has at least a first fixed layer, a first free layer and a first tunnel insulating film sandwiched between the first fixed layer and the first free layer, the second magnetic memory includes a second magneto-resistance element which has at least a second fixed layer, a second free layer and a second tunnel insulating film sandwiched between the second fixed layer and the second free layer, and a magnetic transferring operation is performed while the first and second free layers are being set close to each other with the first and second free layers facing each other.
